(19) United States
(12) Patent Application Publication
(10) Pub. No.: US 2012/0256253 A1
(43) Pub. Date: Oct. 11, 2012

(54) Vertical Memory Devices

(76) Inventors: Sung-Min Hwang, Seoul (KR); Woon-Kyung Lee, Seongnam-si (KR); Young-Jin Kwon, Suwon-si (KR); Tae-Hee Lee, Seoul (KR); Hui-Chang Moon, Yongin-si (KR)

(21) Appl. No.: 13/432,485

(22) Filed: Mar. 28, 2012

(30) Foreign Application Priority Data
Apr. 5, 2011 (KR) 10-2011-0030998

(51) Int. Cl. H01L 29/78

(52) U.S. Cl. 257/329; 257/E29.262

(57) ABSTRACT

Vertical memory devices include a channel, a ground selection line (GSL), a word line, a string selection line (SSL), a pad and an etch-stop layer. The channel extends in a first direction on a substrate. The channel includes an impurity region and the first direction is perpendicular to a top surface of the substrate. At least one GSL, a plurality of the word lines and at least one SSL are spaced apart from each other in the first direction on a sidewall of the channel. The pad is disposed on a top surface of the channel. The etch-stop layer contacts the pad.

### CROSS-REFERENCE TO RELATED APPLICATION

This application claims priority under 35 USC §119 to Korean Patent Application No. 10-2011-0030998, filed on Apr. 5, 2011, in the Korean Intellectual Property Office (KIPO), the entire contents of which is incorporated herein by reference.

### BACKGROUND

1. Field

Example embodiments relate to vertical memory devices and methods of manufacturing the same.

2. Description of the Related Art

Vertical memory devices have been developed in order to increase memory device integration density. In a method of manufacturing a vertical memory device, after alternately depositing a plurality of memory cells and insulation layers, the memory cells and the insulation layers may be etched to form an opening. Polysilicon may be deposited in the opening to form a channel. Additionally, impurities may be doped into an upper portion of the channel.

### SUMMARY

Example embodiments may provide vertical memory devices with enhanced threshold voltage characteristics. Example embodiments may provide methods of manufacturing vertical memory devices with enhanced threshold voltage characteristics.

According to example embodiments, there is provided a vertical memory device. The device includes a channel, a ground selection line (GSL), a word line, a string selection line (SSL), a pad and an etch-stop layer. The channel extends in a first direction on a substrate. The channel includes an impurity region and the first direction is perpendicular to a top surface of the substrate. At least one GSL, a plurality of the word lines and at least one SSL are spaced apart from each other in the first direction on a sidewall of the channel. The pad is disposed on a top surface of the channel. The etch-stop layer contacts the pad.

According to at least one example embodiment, the impurity region may be formed at a portion of the channel adjacent to the SSL. According to at least one example embodiment, the impurity region may have a uniform depth from the top surface of the channel. According to at least one example embodiment, the channel may have a cup shape. According to at least one example embodiment, the etch-stop layer may be disposed on a sidewall of the pad. According to at least one example embodiment, the etch-stop layer may have a top surface coplanar with that of the pad. According to at least one example embodiment, the etch-stop layer may have a double-layered structure of silicon oxide/silicon nitride or a triple-layered structure of silicon oxide/silicon nitride/a metal oxide.

According to example embodiments, there is provided a method of manufacturing a vertical memory device. In the method, a channel is formed on a substrate. The channel extends in a first direction perpendicular to a top surface of the substrate. A preliminary pad is formed on the channel. Insulation layer patterns and sacrificial layer patterns are alternately and repeatedly formed along the first direction on sidewalls of the channel and the preliminary pad. The sacrificial layer patterns are removed to form a plurality of first gaps exposing the sidewall of the channel and a second gap exposing the sidewall of the preliminary pad between the insulation layer patterns. The second gap has a smaller width than that of the first gap. An etch-stop layer is formed in the second gap. A gate structure is formed in each first gap. An uppermost insulation layer pattern is removed until the etch-stop layer is exposed to expose an upper portion of the preliminary pad. A first impurity is implanted through the exposed upper portion of the preliminary pad to form an impurity region in the channel.

According to at least one example embodiment, the impurity region may have a uniform depth from a top surface of the channel and the impurity region may be formed at a portion of the channel adjacent to an uppermost gate structure of the gate structures. According to at least one example embodiment, in forming the channels, insulation layers and sacrificial layers may be alternately and repeatedly formed on the substrate. An opening may be formed through the insulation layers and the sacrificial layers to expose the substrate. A channel layer may be formed on a sidewall and a bottom of the opening and on an uppermost insulation layer. A filling layer that fills a remaining portion of the opening may be formed on the channel layer. Upper portions of the filling layer and the channel layer may be planarized until a top surface of the uppermost insulation layer is exposed to form a filling layer pattern and the channel.

According to at least one example embodiment, forming the insulation layer patterns and the sacrificial layer patterns may be performed by partially removing the insulation layers and the sacrificial layers between the channels. According to at least one example embodiment, a second impurity may be further implanted into the preliminary pad after forming the impurity region. According to at least one example embodiment, in forming the gate structure, a tunnel insulation layer, a charge trap layer and a blocking layer may be sequentially formed on surfaces of the insulation layer patterns and on the sidewall of the channel exposed by the first gaps. A gate electrode that fills a remaining portion of each first gap may be formed.

According to at least one example embodiment, the second gap may be filled with the tunnel insulation layer, the charge trap layer and the blocking layer to form the etch-stop layer therein. According to at least one example embodiment example embodiments, the second gap may be filled with the tunnel insulation layer, or the tunnel insulation layer and the charge trap layer to form the etch-stop layer therein. According to at least one example embodiment, an etch stop layer may be formed adjacent to a pad that may be formed at an upper portion of a channel of a vertical memory device. By the etch-stop layer, an upper portion the pad may be exposed by a uniform height or length. Thus, impurities may be implanted through the exposed portion of the pad to form an impurity region in the channel at a uniform depth or position. As a result, a transistor including the channel may have enhanced threshold voltage characteristics.

According to at least one example embodiment, a vertical memory device includes a channel on and extending perpendicularly to a support layer, a pad on the channel, the channel between the pad and the support layer, and an etch-stop layer adjacent to the pad.

### BRIEF DESCRIPTION OF THE DRAWINGS

Example embodiments will be more clearly understood from the following brief description taken in conjunction with the accompanying drawings. FIGS. 1-40 represent non-limiting, example embodiments as described herein.

FIGS. 1A, 1B and 1C are a perspective diagram, a local perspective diagram and a cross-sectional view, respectively, illustrating vertical memory devices in accordance with example embodiments;

FIGS. 2-13 are cross-sectional diagrams illustrating methods of manufacturing a vertical memory device of FIGS. 1A-1C in accordance with example embodiments;

FIGS. 14-20 are cross-sectional diagrams illustrating methods of manufacturing vertical memory devices in accordance with other example embodiments;

FIGS. 21-26 are cross-sectional diagrams illustrating methods of manufacturing vertical memory devices in accordance with still other example embodiments;

FIG. 27 is a cross-sectional diagram illustrating methods of manufacturing vertical memory devices in accordance with still other example embodiments;

FIGS. 28A and 28B are a perspective diagram and a local perspective diagram, respectively, illustrating vertical memory devices in accordance with example embodiments;

FIGS. 29-38 are perspective diagrams illustrating methods of manufacturing a vertical memory device of FIGS. 28A and 28B in accordance with example embodiments;

FIG. 39 is a schematic diagram illustrating memory cards according to example embodiments; and

FIG. 40 is a block diagram illustrating electronic systems according to example embodiments.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments will now be described more fully with reference to the accompanying drawings, in which example embodiments are shown. Example embodiments may, however, be embodied in many different forms and should not be construed as limited to embodiments set forth herein; rather, these example embodiments are provided so that this description will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element, there are no intervening elements present. Like numerals indicate like elements throughout. As used herein, the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein specify the presence of stated features, integers, steps, operations, elements, and/or components, but do not preclude the presence or addition of one or more other features, integers, steps, operations, elements, components, and/or groups thereof

Example embodiments are described herein with reference to cross-sectional illustrations that are schematic illustrations of idealized example embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

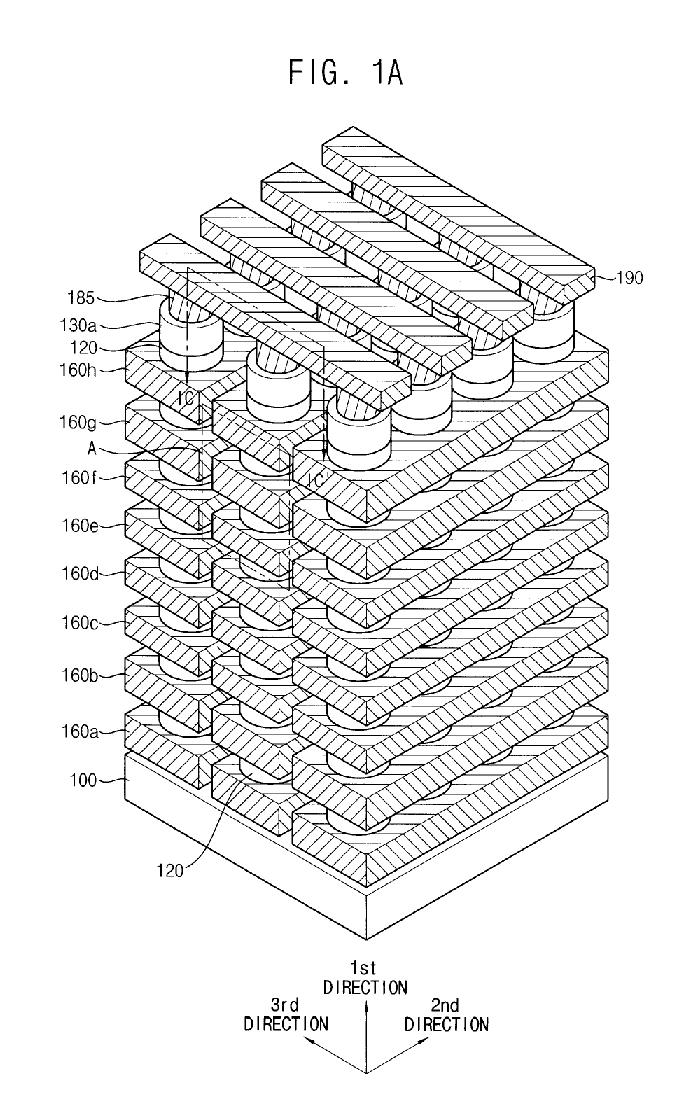

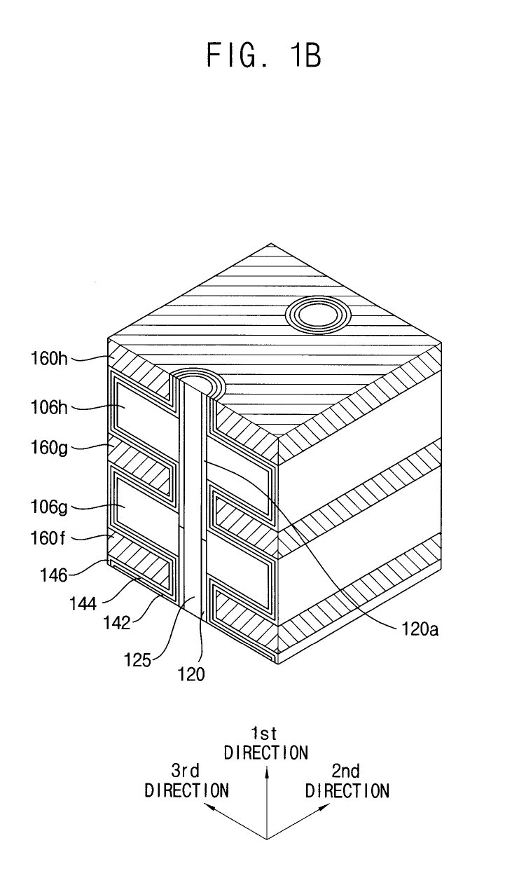

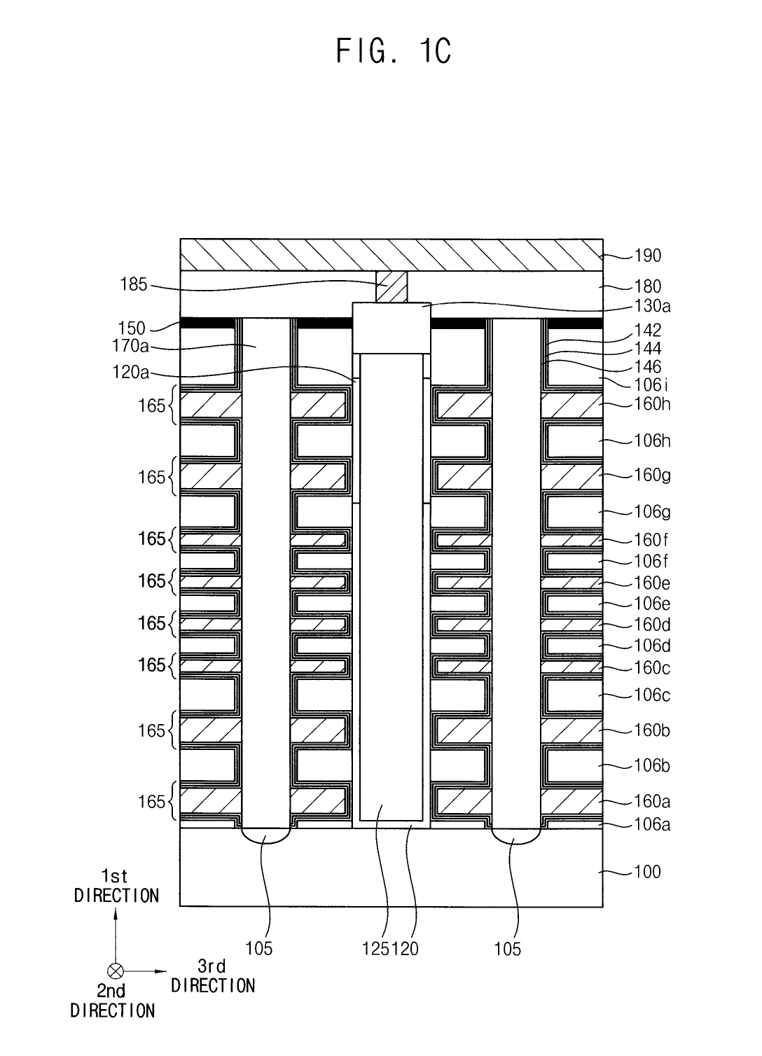

FIGS. 1A, 1B and 1C are a perspective diagram, a local perspective diagram and a cross-sectional view, respectively, illustrating vertical memory devices in accordance with example embodiments. FIG. 1B is a magnified perspective diagram of region A of a vertical memory device illustrated in FIG. 1A. FIG. 1C is a cross-sectional view of a vertical memory device illustrated in FIG. 1A taken along a line 1C-1C′. Referring to FIGS. 1A, 1B and 1C, a vertical memory device may include a channel 120, a pad 130a, a plurality of gate structures 165 and an etch-stop layer 150. The vertical memory device may include a second impurity region 105 and a bit line 190.

The channel 120 may extend in a first direction substantially vertical to a top surface of the substrate 100. According to example embodiments, the channel 120 may be substantially cup shaped, and/or a substantially hollow and cylindrically shaped. According to example embodiments, a plurality of the channels 120 may be along a second direction substantially parallel to the top surface of the substrate 100 that may define a channel row. A plurality of the channel rows may be disposed along a third direction substantially perpendicular to the second direction.

The channel 120 may include, for example, polysilicon and/or single crystalline silicon. The channel 120 may include a first impurity region 120a that may be doped with p-type impurities (e.g., indium and/or gallium). According to example embodiments, the first impurity region 120a may be at a portion of the channel 120 adjacent to gate electrodes 160g and 160h that may serve as a string selection line (SSL). A depth of the first impurity region 120a may be a uniform depth regardless of a location of the channel 120. A filling layer pattern 125 may be in a space defined by the channel 120. The filling layer pattern 125 may be substantially pillar shaped. The filling layer pattern 125 may include an insulating material, for example, an oxide.

A pad 130a may be on the filling layer pattern 125 and the channel 120. The pad 130a may be electrically connected to a bit line 190 via a bit line contact 185. The pad 130a may serve as a source/drain region from/to which charges may be moved through the channel 120. The pad 130a may include, for example, doped polysilicon. According to example embodiments, the pad 130a may include polysilicon doped with n-type impurities (e.g., phosphorous, arsenic, and/or the like). The gate structures 165 may be spaced apart from each other along the first direction on the substrate 100. According to example embodiments, each gate structure 165 may enclose a sidewall of of the channel 120 and may extend in the second direction.

First insulation layer patterns 106 (e.g., 106b-106h) may be between adjacent gate structures 165. The first insulation layer patterns 106 may include, for example, a silicon oxide (e.g., silicon dioxide (SiO₂), silicon oxycarbide (SiOC) and/or silicon oxyfluoride (SiOF)). The first insulation layer patterns 106 (e.g., 106a and 106i) may be between the gate structure 165 and the etch-stop layer 150 and between the gate structure 165 and the substrate 100. Each gate structure 165 may include a tunnel insulation layer 142, a charge trap layer 144, a blocking layer 146 and a gate electrode 160 that may be sequentially stacked. The tunnel insulation layer 142, the charge trap layer 144 and the blocking layer 146 may be sequentially formed on an outer sidewall of the channel 120 and on the first insulation layer pattern 106. According to some example embodiments, the tunnel insulation layer 142 may be formed only on the outer sidewall of the channel 120. According to at least one example embodiment, the tunnel insulation layer 142, the charge trap layer 144 and the blocking layer 146 may not be formed on a sidewall of the first insulation layer pattern 106.

According to example embodiments, the tunnel insulation layer 142 may include a silicon oxide and the charge trap layer 144 may include a nitride, for example, silicon nitride and/or a metal oxide. According to example embodiments, the blocking layer 146 may include a silicon oxide and/or a metal oxide (e.g., aluminum oxide, hafnium oxide, lanthanum oxide, lanthanum aluminum oxide, lanthanum hafnium oxide, hafnium aluminum oxide, titanium oxide, tantalum oxide and/or zirconium oxide). According to some example embodiments, the blocking layer 146 may be a multi-layered structure of a silicon oxide layer and a metal oxide layer.

According to example embodiments, the gate electrode 160 may include a metal and/or a metal nitride of low electrical resistance. For example, the gate electrode 160 may include tungsten, tungsten nitride, titanium, titanium nitride, tantalum, tantalum nitride, platinum and/or the like. According to an example embodiment, the gate electrode 160 may be a multi-layered structure including a barrier layer that may contain a metal nitride and a metal layer.

Two lowermost gate electrodes 160a and 160b may serve as a ground selection line(s) (GSL) and two uppermost gate electrodes 160g and 160h may serve as a SSL(s). Four gate electrodes 160c, 160d, 160e and 160f between the GSL and the SSL may each serve as a word line. Each of the SSL and the GSL may be formed at two levels and the word line may be formed at four levels. However, the number of the GSL(s), the SSL(s) and the word line(s) may not be limited thereto. For example, each GSL and SSL may be at one level and word lines may be formed at 2, 8 or 16 levels.

The etch-stop layer 150 may extend along the second direction surrounding a sidewall of the pad 130a. According to example embodiments, the etch stop layer 150 may be on a top surface of an uppermost first insulation layer pattern 106i. The etch-stop layer 150 may include, for example, a silicon oxide, a metal oxide and/or silicon nitride. According to example embodiments, the etch-stop layer 150 may be a multi-layered structure including the tunnel insulation layer 142, the charge trap layer 144 and the blocking layer 146. According to other example embodiments, the etch-stop layer 150 may be a single-layered structure including the tunnel insulation layer and/or a double-layered structure including the tunnel insulation layer 142 and the charge trap layer 144, for example. As used herein, the etch-stop layer 150 may include a material that is compatible with end-point detection, that acts as a planarization stop, and/or the like.

A second insulation layer pattern 170a may be between structures each of which may include the gate structures 165 and the first insulation layer patterns 106 alternately and repeatedly stacked on each other. The second insulation layer pattern 170a may include an insulating material (e.g., an oxide). A second impurity region 105 that may serve as a common source line (CSL) may be formed at an upper portion of the substrate 100 beneath the second insulation layer pattern 170a. According to an example embodiment, a metal silicide pattern (not illustrated), for example a cobalt silicide pattern, may be on the second impurity region 105.

The bit line 190 may be electrically connected to the pad 130a via the bit line contact 185, and thereby electrically connected to the channel 120. The bit line 190 may include, for example, a metal, a metal nitride, doped polysilicon and/or the like. According to example embodiments, the bit line 190 may extend in the third direction and a plurality of the bit lines 190 may be disposed along the second direction. The bit line contact 185 may make contact with the pad 130a through an insulating interlayer 180. The bit line contact 185 may include, for example, a metal, a metal nitride, doped polysilicon and/or the like.

The insulating interlayer 180 may be on the etch-stop layer 150, the second insulation layer pattern 170a and the pad 130a. According to example embodiments, the insulating interlayer 180 may include an insulating material (e.g., an oxide). The vertical memory device according to example embodiments may include the etch-stop layer 150 surrounding the sidewall of the pad 130a. The channel 120 may include a uniform first impurity region 120a with a uniform depth from a top surface of the channel. Threshold voltage characteristics of a transistor that includes the channel 120, specifically a string selection transitor (SST) that may include the SSL, may be enhanced.

According to other example embodiments, a top surface of the etch-stop layer 150 may be coplanar with that of the pad 130a. According to still other example embodiments, a top surface of the etch-stop layer 150 may be over a top surface of the pad 130a.

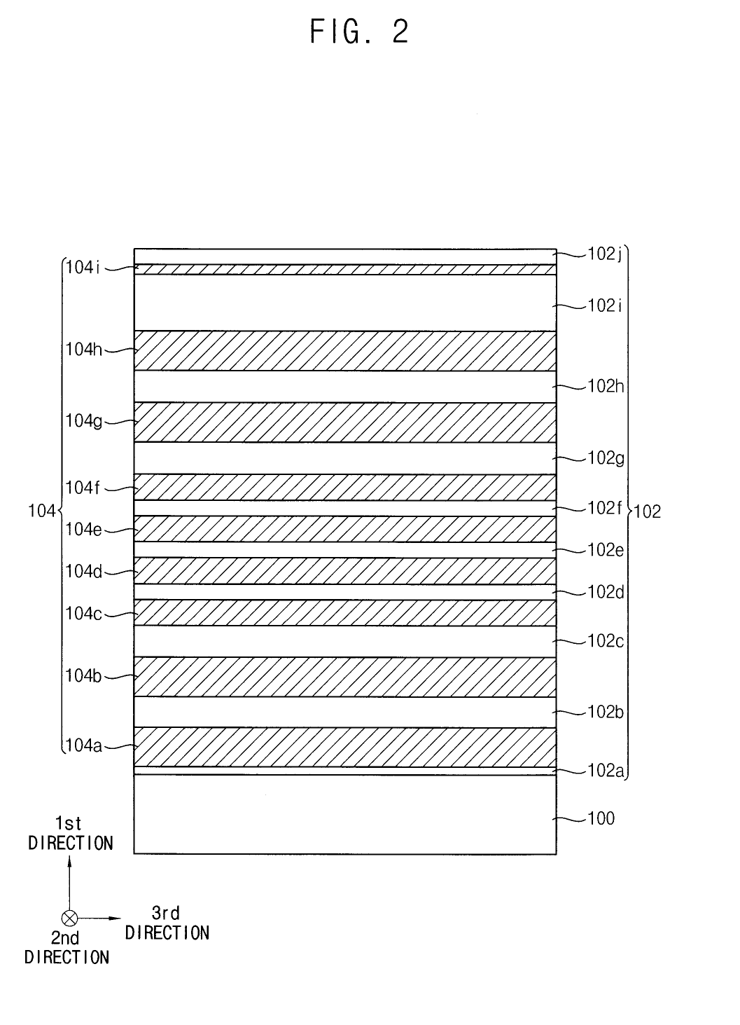

FIGS. 2-13 are cross-sectional diagrams illustrating methods of manufacturing a vertical memory device of FIGS. 1A-1C in accordance with example embodiments. Referring to FIG. 2, a first insulation layer 102 and a sacrificial layer 104 may be alternately and repeatedly formed on a substrate 100. A plurality of the first insulation layers 102 (e.g., 102a-102j) and a plurality of the sacrificial layers 104 (e.g., 104a-104i) may be alternately formed, one on the other, at a plurality of levels, respectively. For example, a sacrificial layer 104 may be between each adjacent pair of insulation layers 102. The substrate 100 may include a semiconductor material, for example, single crystalline silicon and/or germanium. Although example embodiments are described with reference to a semiconductor substrate, as used herein, a substrate is a support layer that may be, for example, a bulk semiconductor, an epitaxial layer, a low temperature substrate and/or the like.

According to example embodiments, the first insulation layers 102 and the sacrificial layers 104 may be formed by, for example, a chemical vapor deposition (CVD) process, a plasma enhanced chemical vapor deposition (PECVD) process, an atomic layer deposition (ALD) process and/or the like. A lowermost first insulation layer 102a, which may be formed directly on a top surface of the substrate 100, may be formed by a thermal oxidation process. According to example embodiments, the first insulation layers 102 may be formed using a silicon oxide, for example, silicon dioxide (SiO₂), silicon oxycarbide (SiOC) and/or silicon oxyfluoride (SiOF). The sacrificial layers 104 may be formed using a material with etch selectivity to the first insulation layers 102 and the substrate 100. The sacrificial layers 104 may be formed using a material that may be easily removed by a wet etch process. For example, the sacrificial layers 104 may be formed using silicon nitride and/or silicon boronitirde.

According to example embodiments, a thickness of an uppermost sacrificial layer 104i may be less than that of other sacrificial layers 104a-104h. Thicknesses of the sacrificial layers 104a and 104b that may be at levels for forming a GSL, and the sacrificial layers 104g and 104h that may be at levels for forming a SSL, may be greater than that of the sacrificial layers 104c, 104d, 104e and 104f that may be at levels for forming word lines.

The number of the first insulation layers 102 and the number of the sacrificial layers 104 that may be stacked on the substrate 100 may vary according to a desired number of the GSL(s), the word line(s) and the SSL(s). According to example embodiments, each of the GSL(s) and the SSL(s) may be formed at 2 levels, and word lines may be formed at 4 levels. The sacrificial layers 104 may be formed at 8 levels, and the first insulation layers 102 may be formed at 9 levels. According to some example embodiments, each of the GSL and the SSL may be formed at a single level, and the word line may be formed at 2, 8 or 16 levels. The sacrificial layers 104 may be formed at 4, 10 or 18 levels, and the first insulation layers 102 may be formed at 5, 11 or 19 levels. However, the number of the first insulation layers 102 and the sacrificial layers 104 are not limited herein.

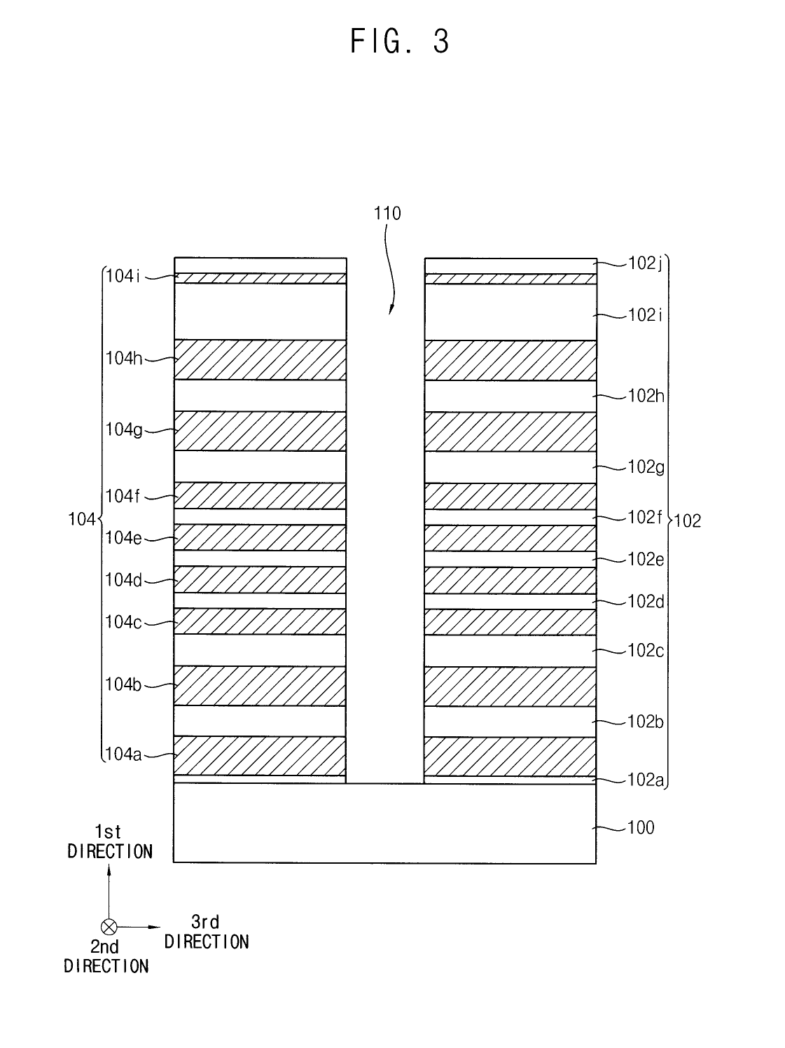

Referring to FIG. 3, a first opening 110 may be formed through the first insulation layers 102 and the sacrificial layers 104 to expose a top surface of the substrate 100. According to example embodiments, a hard mask (not illustrated) may be formed on the uppermost first insulation layer 102j, and the first insulation layers 102 and the sacrificial layers 104 may be dry etched using the hard mask as an etch mask to form the first opening 110. The first opening 110 may extend in a first direction substantially perpendicular to the top surface of the substrate 100. According to example embodiments, a plurality of the first openings 110 may be formed regularly along a second direction substantially parallel to the top surface of the substrate 100 and a third direction substantially perpendicular to the second direction.

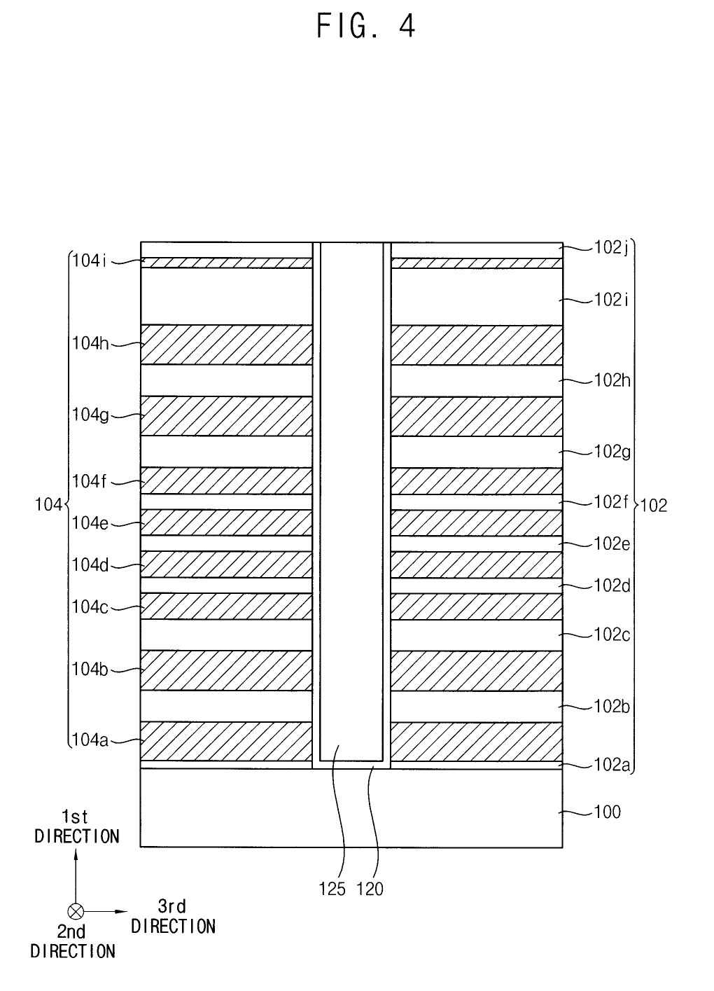

Referring to FIG. 4, a channel 120 may be formed on surfaces inside the first opening 110, and a filling layer pattern 125 may be formed in the channel 120 to fill a remaining portion of the first opening 110. A channel layer may be formed on the surfaces inside the first opening 110 and on the uppermost first insulation layer 102j. A filling layer may be formed on the channel layer to fill the remaining portion of the first opening 110. According to example embodiments, the channel layer may be formed using, for example, polysilicon and/or amorphous silicon. The filling layer may be formed using an insulating material, for example, an oxide. According to at least one example embodiment, the channel layer may be formed using polysilicon and/or amorphous silicon, and a heat treatment and/or a laser treatment may be performed on the channel layer to transform the poysilicon and/or amorphous silicon into single crystalline silicon. Defects included in the channel layer may be removed and properties of the channel 120 may be enhanced.

Upper portions of the filling layer and the channel layer may be planarized until a top surface of the first insulation layer 102j is exposed to form the filling layer pattern 125 and the channel 120. The channel 120 may be substantially cup shaped, and/or hollow and cylindrically shaped. The planarization process may include, for example, a chemical mechanical polishing (CMP) process.

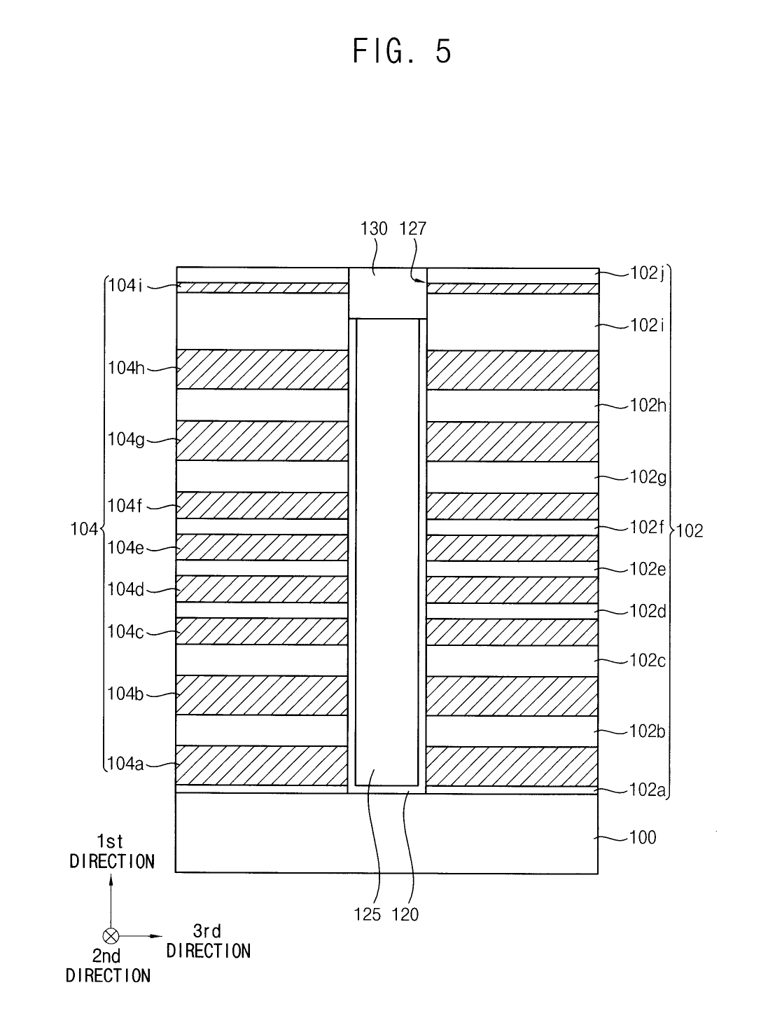

Referring to FIG. 5, upper portions of the filling layer pattern 125 and the channel 120 may be removed to form a recess 127 and a preliminary pad 130 filling the recess 127 may be formed. The upper portions of the filling layer pattern 125 and the channel 120 may be removed by (e.g., using an etch-back process) to form the recess 127. A preliminary pad layer (not illustrated) filling the recess 127 may be formed on the filling layer pattern 125, the channel 120 and the first insulation layer 102j An upper portion of the preliminary pad layer may be planarized until the top surface of the first insulation layer 102j is exposed to form the preliminary pad 130. According to example embodiments, the preliminary pad layer may be formed using, for example, polysilicon and/or amorphous silicon. The planarization may include, for example, a CMP process.

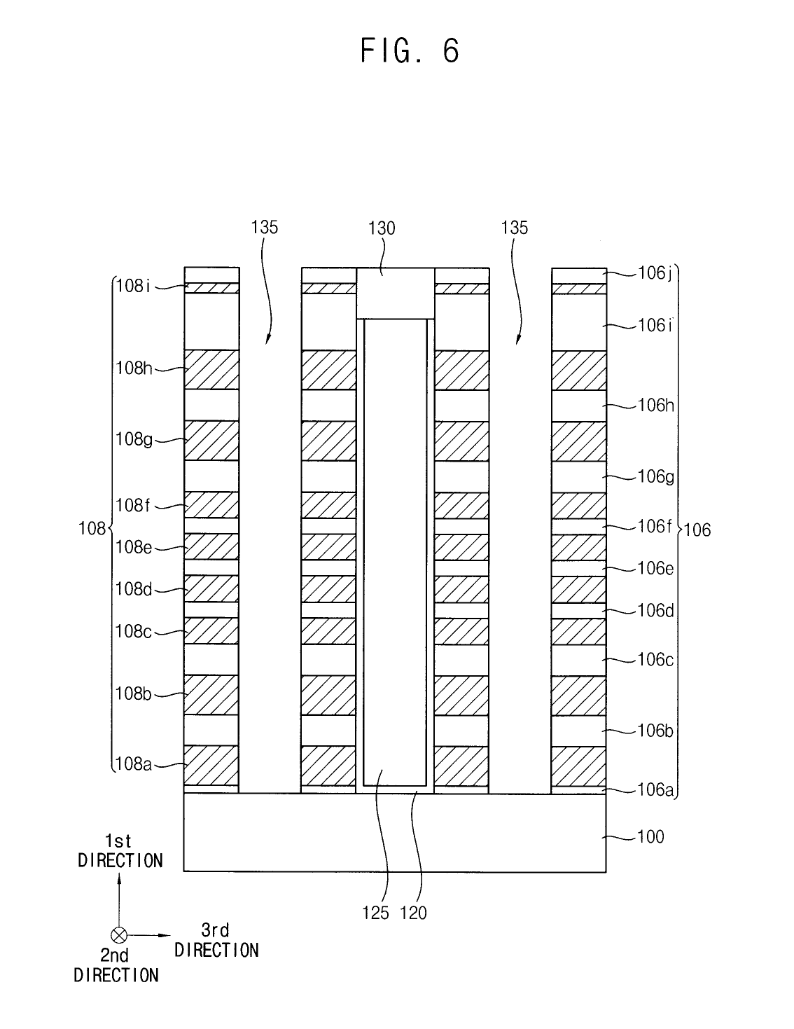

Referring to FIG. 6, second openings 135 may be formed through the first insulation layers 102 and the sacrificial layers 104 to expose the top surface of the substrate 100. According to example embodiments, a hard mask (not illustrated) may be formed on the uppermost first insulation layer 102j. The first insulation layers 102 and the sacrificial layers 104 may be partially and sequentially etched using the hard mask as an etch mask to form the second opening 135.

According to example embodiments, the second openings 135 may extend in the second direction and a plurality of the second openings 135 may be formed along the third direction. By forming the second openings 135, the first insulation layers 102 and the sacrificial layers 104 may be transformed into first insulation layer patterns 106 (e.g., 106a-106j) and sacrificial layer patterns 108 (e.g., 108a-108i). The first insulation patterns 106 and the sacrificial layer patterns 108 at each level may extend in the second direction. The first insulation layer patterns 106 and the sacrificial layer patterns 108 may be repeatedly and alternately stacked in the first direction to form a pattern structure. A plurality of the pattern structures may be formed along the third direction.

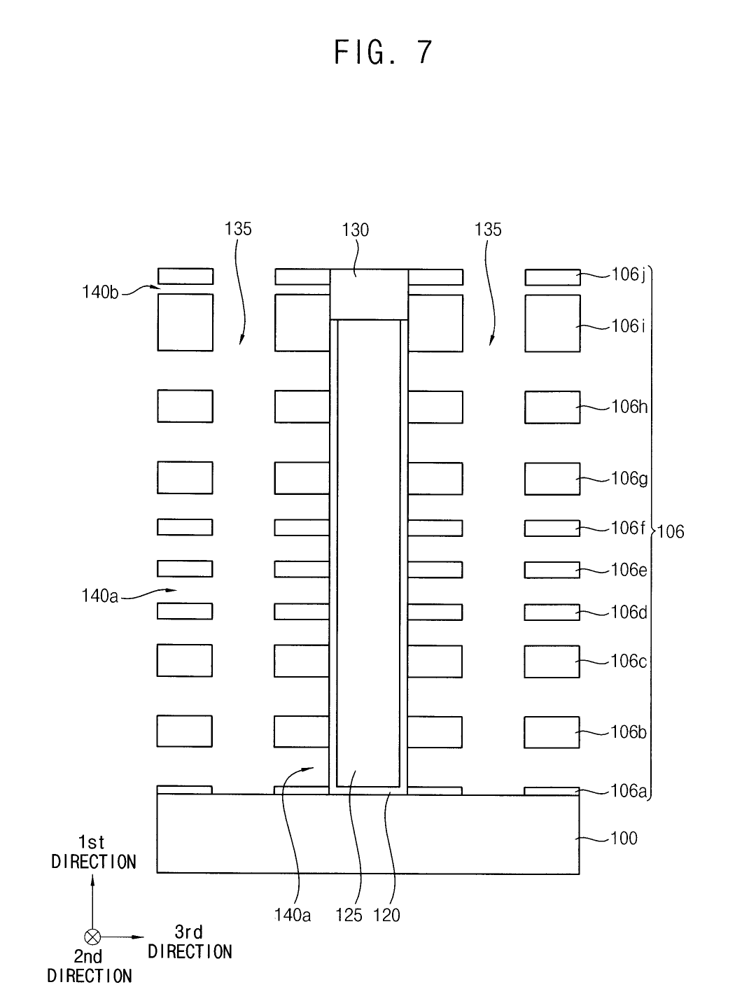

Referring to FIG. 7, the sacrificial layer patterns 108 exposed by the second opening 135 may be removed. According to example embodiments, the sacrificial layer patterns 108 may be removed by, for example, a wet etch process using an etch solution (e.g., phosphoric acid and/or sulfuric acid). Only the first insulation layer patterns 106 may remain on outer sidewalls of the channel 120 and the preliminary pad 130. First and second gaps 140a and 140b may be formed between the adjacent first insulation layer patterns 106. The first gap 140a may expose the outer sidewall of the channel 120 and the second gap 140b may expose the outer sidewall of the preliminary pad 130. The second gap 140b may be defined by a space from which the uppermost sacrificial layer pattern 108i is removed and other gaps may be referred to as the first gaps 140a. A width of the second gap 140b may be less than a width of each first gap 140a because the uppermost sacrificial layer pattern 180i may be formed thinner than other sacrificial layer patterns 108a-108h.

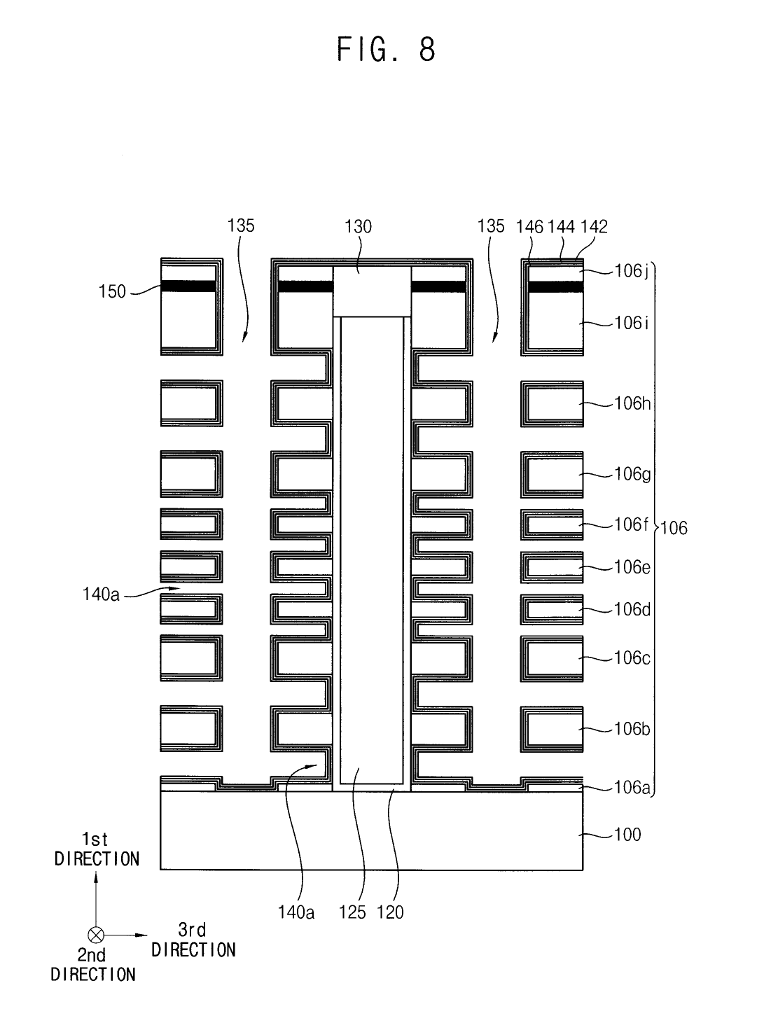

Referring to FIG. 8, a tunnel insulation layer 142, a charge trap layer 144 and a blocking layer 146 may be sequentially formed on the exposed outer sidewall of the channel 120, surfaces of the first insulation layer patterns 106, the top surface of the substrate 100, a top surface of the preliminary pad 130, and in the second gap 140b. According to example embodiments, the tunnel insulation layer 142 may be formed using, for example, a silicon oxide deposited by a CVD process. According to at least one example embodiment, the tunnel insulation layer 142 may be formed by performing a thermal oxidation process on the exposed outer sidewall of the channel 120 and the tunnel insulation layer 142 may not be formed on the first insulation layer patterns 106.

The charge trap layer 142 may be formed using, for example, a nitride (e.g., silicon nitride and/or a metal oxide). The blocking layer 146 may be formed using, for example, a silicon oxide and/or a metal oxide. The metal oxide may include, for example, aluminum oxide, hafnium oxide, lanthanum oxide, lanthanum aluminum oxide, lanthanum hafnium oxide, hafnium aluminum oxide, titanium oxide, tantalum oxide, zirconium oxide, and/or the like. According to some example embodiments, the blocking layer 146 may be a multi-layered structure including a silicon oxide layer and a metal oxide layer.

The second gap 140b may be filled (e.g., completely filled) with the tunnel insulation layer 142, the charge trap layer 144 and the blocking layer 146 because the second gap 140b may be narrow. According to an example embodiment, the second gap 140b may be filled with the tunnel insulation layer 142 and the charge trap layer 144. According to at least one example embodiment, the second gap 140b may be filled only with the tunnel insulation layer 142. A single layered or a multi-layered structure may be formed in the second gap 140b that may define an etch-stop layer 150. According to some example embodiments, the tunnel insulation layer 142, the charge trap layer 144 and the blocking layer 146 may be formed continuously throughout all the levels.

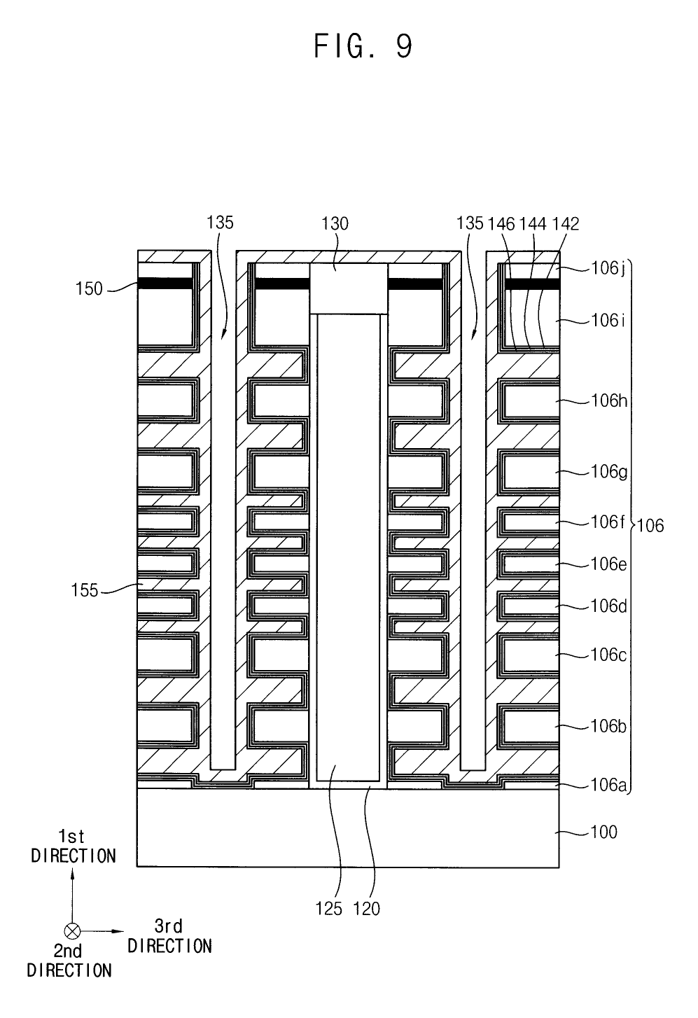

Referring to FIG. 9, a gate electrode layer 155 may be formed on the blocking layer 146 to fill (e.g., sufficiently fill) the first gaps 140a. The gate electrode layer 155 may also partially fill the second opening 135. According to example embodiments, the gate electrode layer 155 may be formed using, for example, a metal and/or a metal nitride. For example, the gate electrode layer may be formed using a low electrical resistance metal and/or metal nitride (e.g., tungsten, tungsten nitride, titanium, titanium nitride, tantalum, tantalum nitride, platinum and/or the like). According to at least one example embodiment, the gate electrode layer 155 may be a multi-layered structure of a barrier layer including a metal nitride and a metal layer including a metal. The gate electrode layer 155 may be formed by, for example, a CVD process and/or an ALD process.

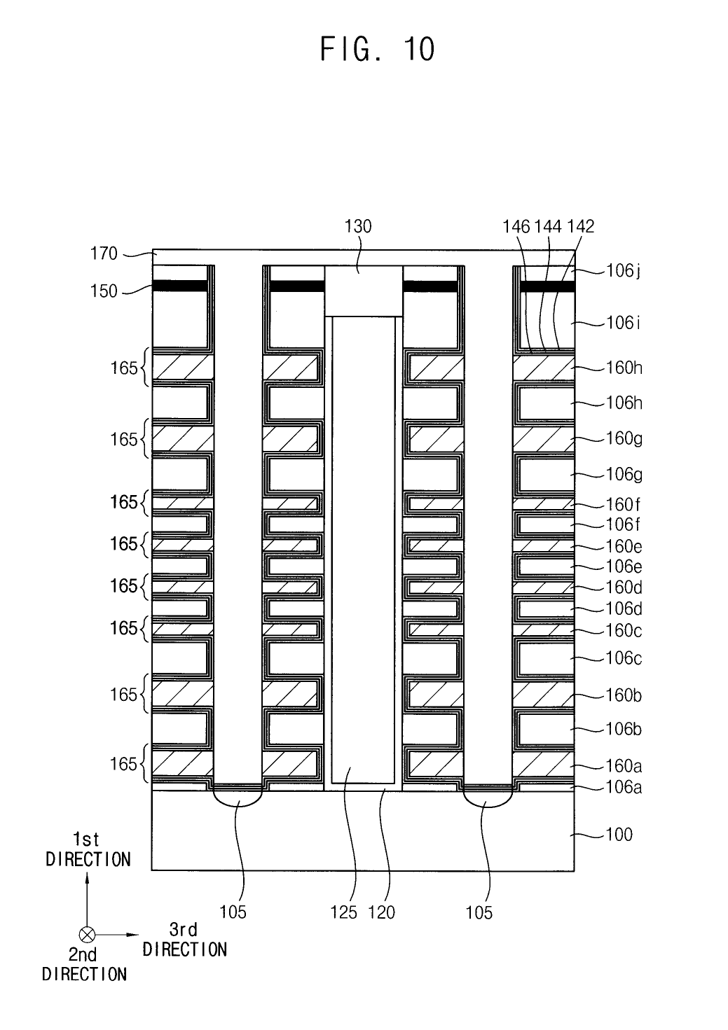

Referring to FIG. 10, the gate electrode layer 155 may be partially removed to form gate electrodes 160 in the first gaps 140a. An upper portion of the gate electrode layer 155 may be planarized until a top surface of an uppermost first insulation layer pattern 106j is exposed. Portions of the tunnel insulation layer 142, the charge trap layer 144 and the blocking layer 146 that may be formed on the top surface of the uppermost first insulation layer pattern 106j may be also removed. A portion of the gate electrode layer 155 that may be formed in the second opening 135 may be removed to form the gate electrodes 160.

Portions of the tunnel insulation layer 142, the charge trap layer 144 and the blocking layer 146 that may be formed on the top surface of the substrate 100 may be also removed. According to example embodiments, the planarization process may include, for example, a CMP process. The gate electrode layer 155 may be partially removed by, for example, a wet etch process. A gate structure 165 including the tunnel insulation layer 142, the charge trap layer 144, the blocking layer 146 and the gate electrode 160 which may be sequentially stacked may be formed in each first gap 140a.

Two lowermost gate electrodes 160a and 160b may serve as the GSL(s) and two uppermost gate electrodes 160g and 160h may serve as the SSL(s). Four gate electrodes 160c, 160d, 160e and 160f between the GSL(s) and the SSL(s) may serve as word lines. According to some example embodiments, portions of the tunnel insulation layer 142, the charge trap layer 144 and the blocking layer 146 formed on sidewalls of the first insulation layer patterns 106 may be removed together with the portion of the gate electrode layer 155. A blocking layer pattern, a charge trap layer pattern and a tunnel insulation layer pattern may be formed in the first gap 140a.

A third opening (not illustrated) may be formed by removing the portions of the gate electrode layer 155, the tunnel insulation layer 142, the charge trap layer 144 and the blocking layer 146 in the second opening 135. The third opening may expose the top surface of the substrate 100 and may extend in the second direction. Impurities may be implanted into the exposed top surface of the substrate 100 to form a second impurity region 105. According to example embodiments, the impurities may include n-type impurities (e.g., phosphorus and/or arsenic). According to example embodiments, the second impurity region 105 may extend in the second direction and serve as a CSL.

According to at least one example embodiment, a metal silicide pattern (not illustrated), for example, a nickel silicide pattern and/or a cobalt silicide pattern, may be formed on the second impurity region 105. A second insulation layer 170 filling the third opening may be formed on the substrate 100, the first insulation layer pattern 106j and the preliminary pad 130.

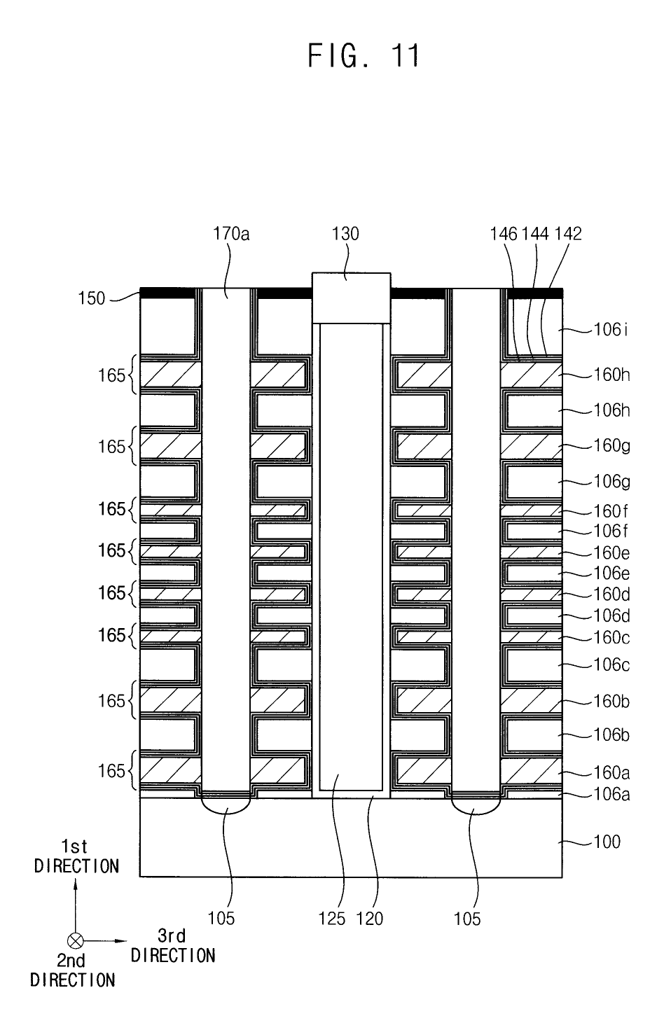

Referring to FIG. 11, portions of the second insulation layer 170, the tunnel insulation layer 142, the charge trap layer 144, the blocking layer 146, and the uppermost first insulation layer pattern 106j may be removed by performing, for example, an etch-back process, until a top surface of the etch-stop layer 150 is exposed to form a second insulation layer pattern 170a. An upper portion of the preliminary pad 130 may be exposed. In example embodiments, the second insulation layer pattern 170a may be formed between structures including the first insulation layer patterns 106, the gate structures 165 and the etch-stop layer 150.

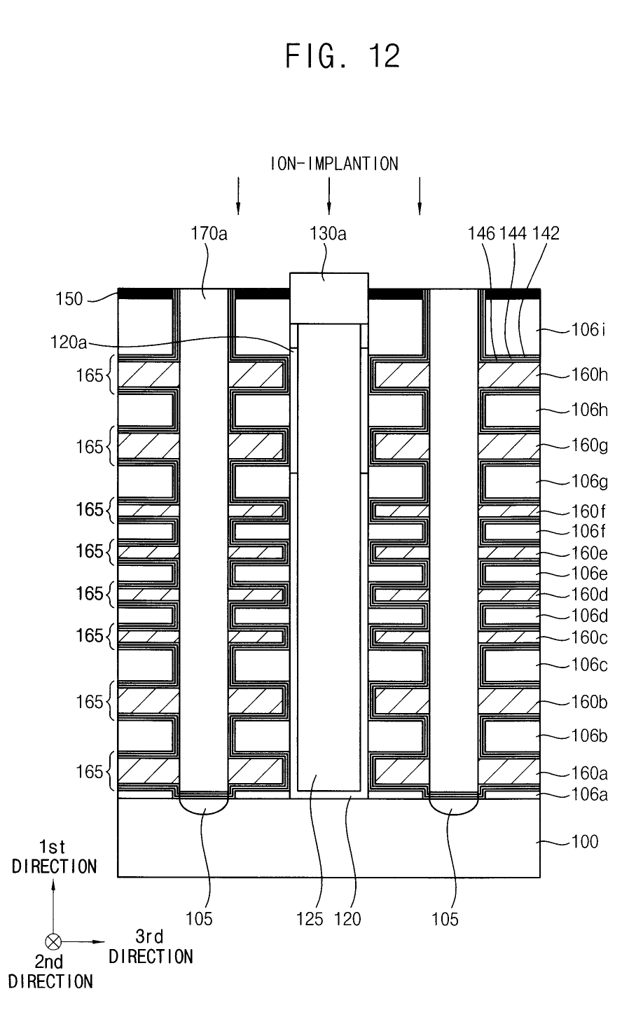

Referring to FIG. 12, a first impurity region 120a may be formed at the channel 120 by a first ion-implantation process. A first impurity may be implanted into the channel 120 through the exposed upper portion of the preliminary pad 130 by a first ion-implantation process to form the first impurity region 120a. According to example embodiments, the first impurities may include, for example, p-type impurities (e.g., indium and/or gallium). According to example embodiments, the first impurity region 120a may be formed at a portion of the channel 120 adjacent to the two uppermost gate electrodes 160g and 160h serving as the SSL(s). The first impurity region 120a may be formed to a uniform depth from a top surface of the channel 120 by the etch-stop layer 150.

If the etch-stop layer 150 is not formed, the first insulation layer pattern 106 and the second insulation layer 170 near the preliminary pad 130 may not be uniformly removed while performing planarization (e.g., an etch-back process) to expose the upper portion of the preliminary pad 130. The exposed upper portion of the preliminary pad 130 may be of an irregular height and/or length along a sidewall thereof. The first impurity implanted into the channel 120 through the exposed preliminary pad 130 may not be uniformly doped to a desired depth and/or position.

According to example embodiments, the etch-stop layer 150 may be formed between the two uppermost insulation layer patterns 106j and 106i. An etch-back process may be performed until the etch-stop layer 150 is exposed. A height of the exposed upper portion of the preliminary pad 130 may be a uniform height along the sidewall thereof, and the first impurity may be doped through the exposed preliminary pad 130 to a uniform depth and/or a uniform position. Threshold voltage characteristics of transistors including the channel 120, for example the SST that may include the SSL adjacent to the first impurity region 120a, may be improved (e.g., reduced threshold voltage distribution).

A second impurity may be implanted into the preliminary pad 130 by a second ion-implantation process that may form a pad 130a. According to example embodiments, the second impurity may include n-type impurities, for example, phosphorous and/or arsenic. The preliminary pad 130 may be exposed to a uniform height and/or length. The second impurity may be uniformly doped into the preliminary pad 130 so that a doping profile of the pad 130a may be a uniform doping profile. According to some example embodiments, the second ion-implantation process may be performed prior to performing the first ion-implantation process.

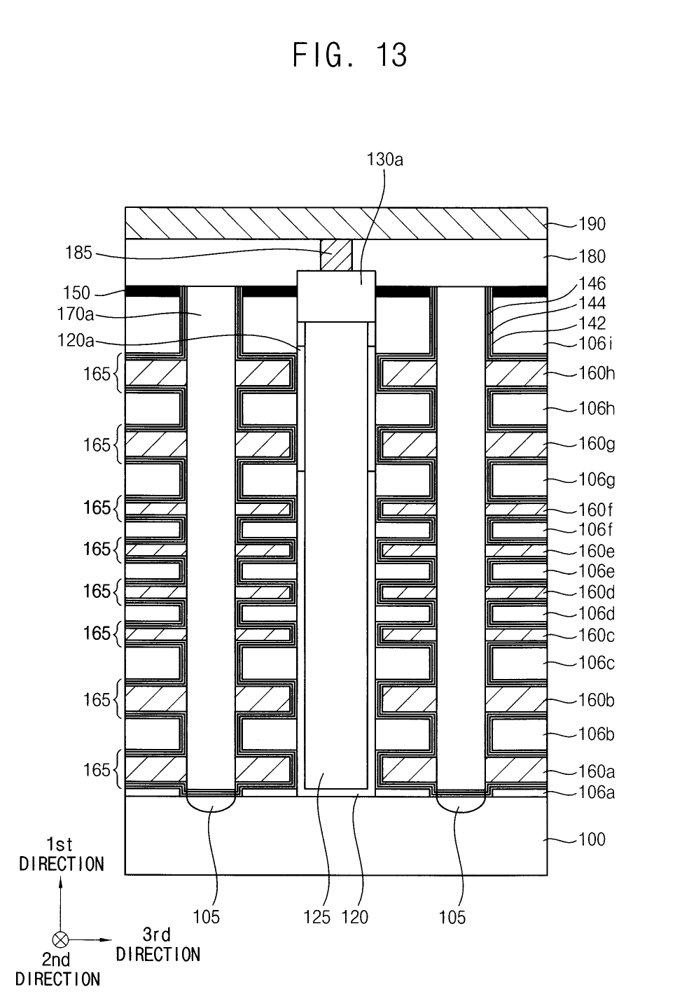

Referring to FIG. 13, an insulating interlayer 180 may be formed on the etch-stop layer 150, the second insulation layer pattern 170a and the pad 130a. The insulating interlayer 180 may be formed using, for example, an insulating material (e.g., a silicon oxide). A bit line contact 185 may be formed through the insulating interlayer 180 to make contact with the pad 130a. The bit line contact 185 may be formed using, for example, a metal, a metal nitride, doped polysilicon, and/or the like. A bit line 190 may be formed on the insulating interlayer 180 so that the insulating interlayer 180 may be electrically connected to the bit line contact 185. The bit line 190 may be formed using, for example, a metal, a metal nitride, doped polysilicon and/or the like. According to example embodiments, the bit line 190 may extend in the third direction and a plurality of the bit lines 190 may be formed along the second direction.

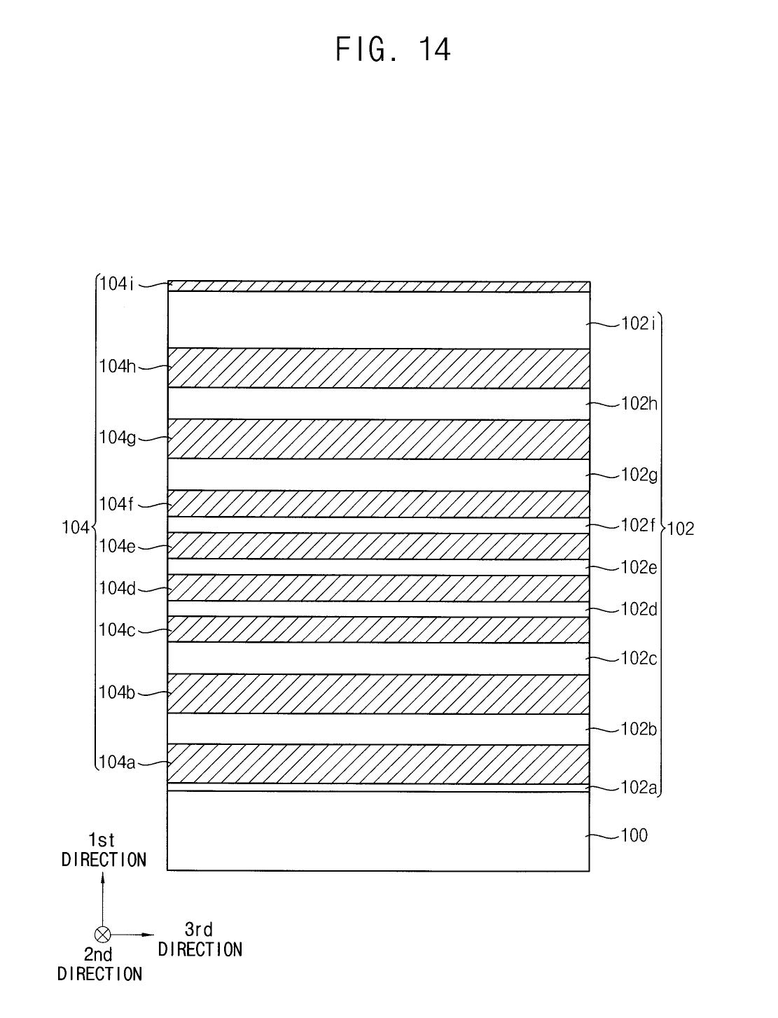

FIGS. 14-20 are cross-sectional diagrams illustrating methods of manufacturing vertical memory devices in accordance with other example embodiments. The vertical memory devices may be substantially the same as or similar to that manufactured by the methods illustrated with reference to FIG. 2-13 except for a position at which the etch-stop layer 150 is formed. Detailed explanations of substantially the same elements and/or methods may be omitted.

Referring to FIG. 14, processes substantially the same as or similar to those illustrated with reference to FIG. 2 may be performed. First insulation layers 102 and sacrificial layers 104 may be alternately and repeatedly formed on a substrate 100 to form a mold structure. An uppermost sacrificial layer 104i may be formed at a top position of the mold structure. The uppermost sacrificial layer 104i may thinner than any of sacrificial layers 104a-104h.

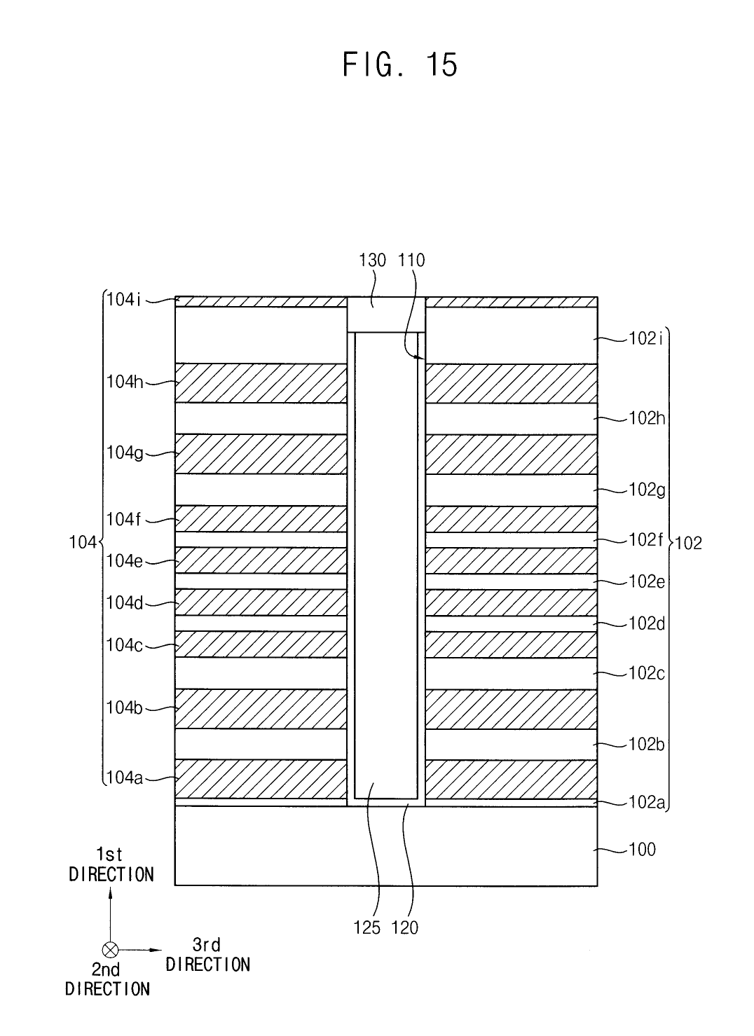

Referring to FIG. 15, processes substantially the same as or similar to those illustrated with reference to FIGS. 3-5 may be performed. A first opening 110 that may expose the substrate 100 may be formed through the sacrificial layers 104 and the first insulation layers 102. A channel 120 and a filling layer pattern 125 may be formed in the first opening 110 and a preliminary pad 130 that may fill a remaining portion of the first opening 110 may be formed on the channel 120 and the filling layer pattern 125.

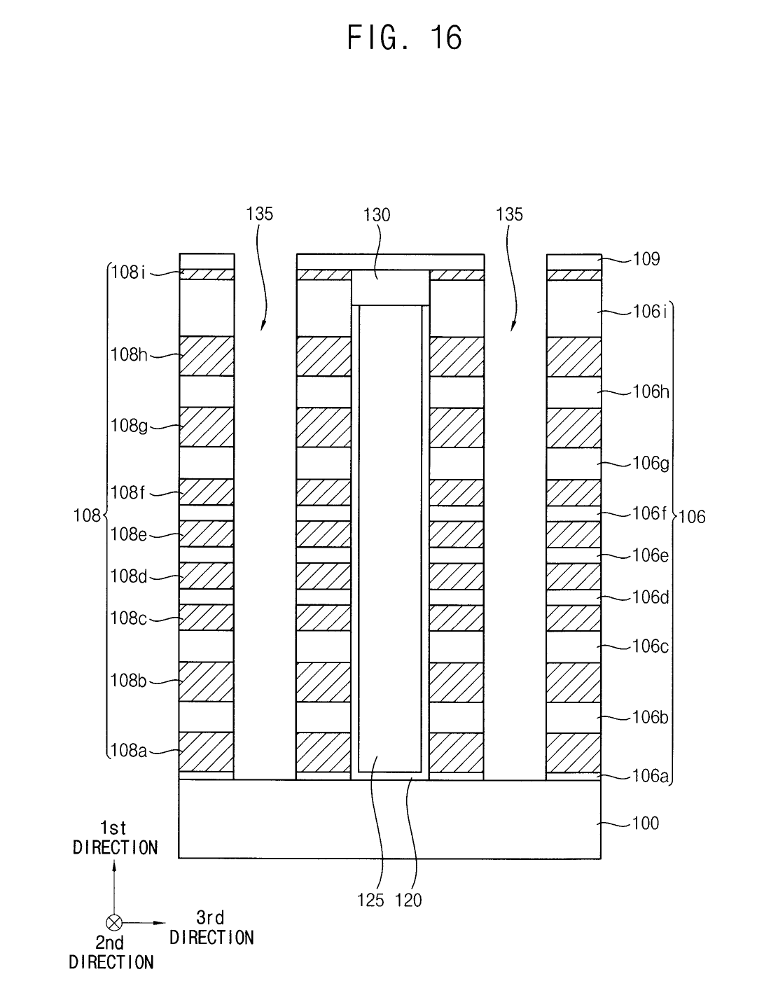

Referring to FIG. 16, an upper insulation layer (not illustrated) may be formed on the sacrificial layer 104i and the preliminary pad 130. According to example embodiments, the upper insulation layer may be formed using, for example, a silicon oxide, a silicon oxycarbide, a silicon oxyfluoride and/or the like. The upper insulation layer may be formed using a material substantially the same as that of the first insulation layers 102.

Processes substantially the same as or similar to those illustrated with reference to FIG. 6 may be performed. A second opening 135 may expose the substrate 100 through the upper insulation layer, the sacrificial layers 104 and the first insulation layers 102. By forming the second opening 135, the upper insulation layer, the sacrificial layers 104 and the first insulation layers 102 may be transformed into an upper insulation layer pattern 109, sacrificial layer patterns 108 and first insulation layer patterns 106, respectively. The upper insulation layer pattern 109, the sacrificial layer pattern 108 and the first insulation layer pattern 106 at each level may extend in a second direction. A structure including the first insulation layer pattern 106, the sacrificial layer pattern 108 and the upper insulation layer pattern 109 may be repeatedly stacked in a first direction that may be repeatedly disposed along a third direction

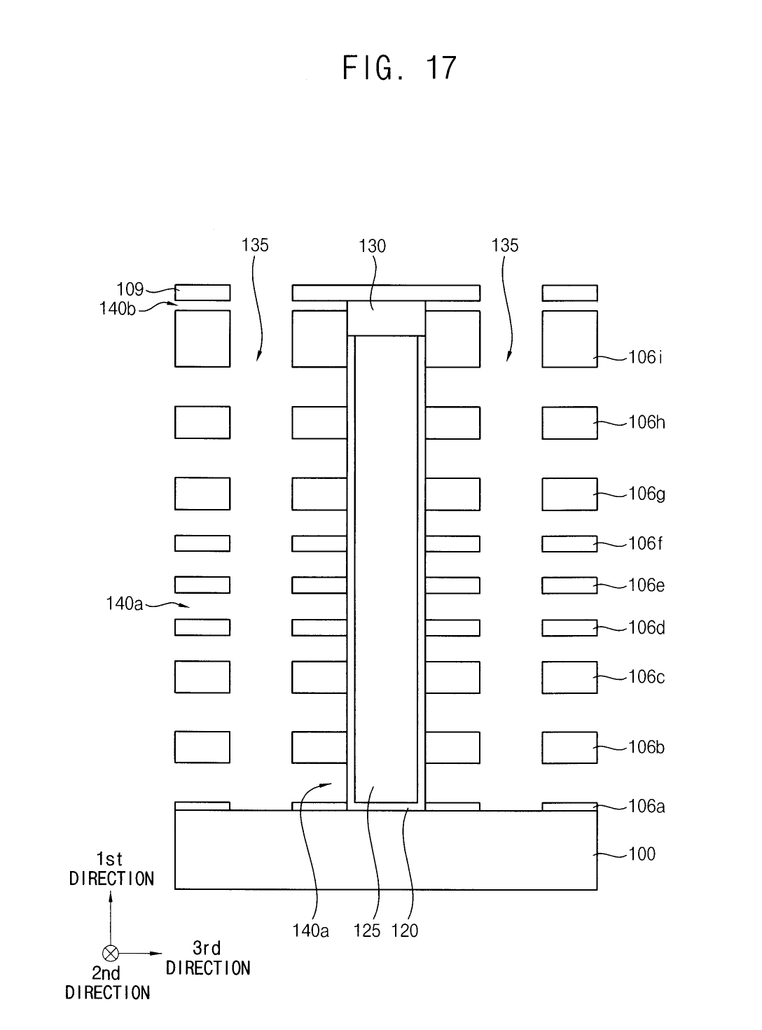

Referring to FIG. 17, processes substantially the same as or similar to those illustrated with reference to FIG. 7 may be performed. The sacrificial layer patterns 108 that may be exposed inside the second opening 135 may be removed to form first gaps 140a and a second gap 140b. The first gaps 140a may be formed between the adjacent first insulation layer patterns 106. The second gap 140b may be formed between the uppermost insulation layer pattern 109 and an uppermost first insulation layer pattern 106i. According to example embodiments, a width of the second gap 140b may be less than a width of the first gaps 140a.

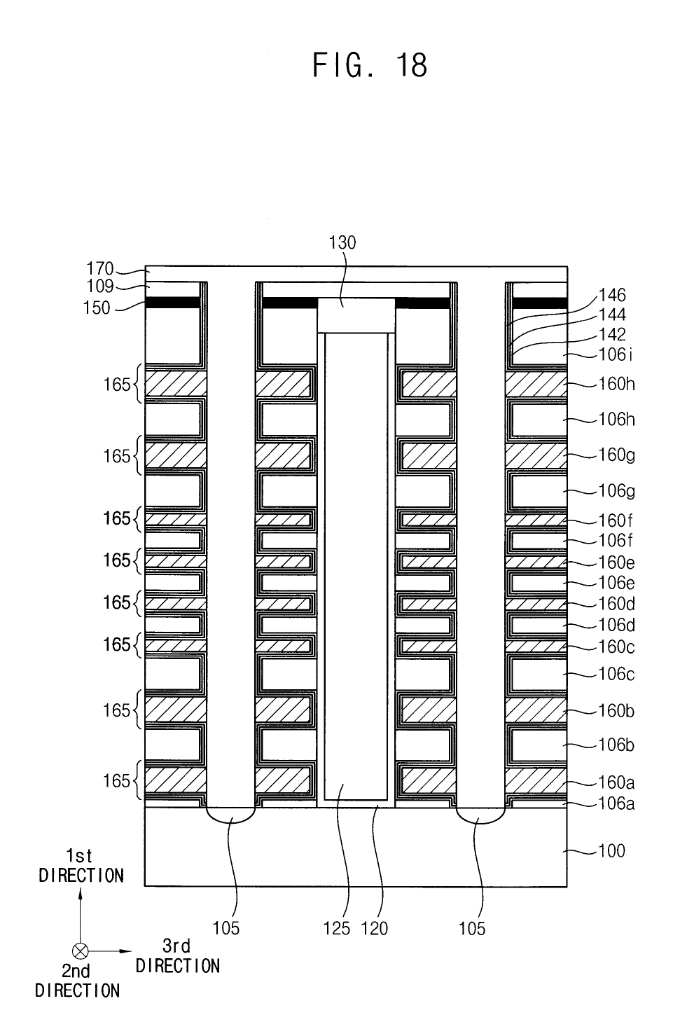

Referring to FIG. 18, processes substantially the same as or similar to those illustrated with reference to FIGS. 8-10 may be performed. A gate structure 165 that may include a tunnel insulation layer 142, a charge trap layer 144 and a blocking layer 146 and a gate electrode 160 may be formed in the first gap 140a at each level. An etch-stop layer 150 including the tunnel insulation layer 142, the charge trap layer 144 and/or the blocking layer 146 may be formed in the second gap 140b. A second impurity region 105 may be formed at an upper portion of the substrate 100 that may be exposed by the second opening 135. A second insulation layer 170 that may fill the second opening 135 may be formed on the substrate 100 and the upper insulation layer pattern 109.

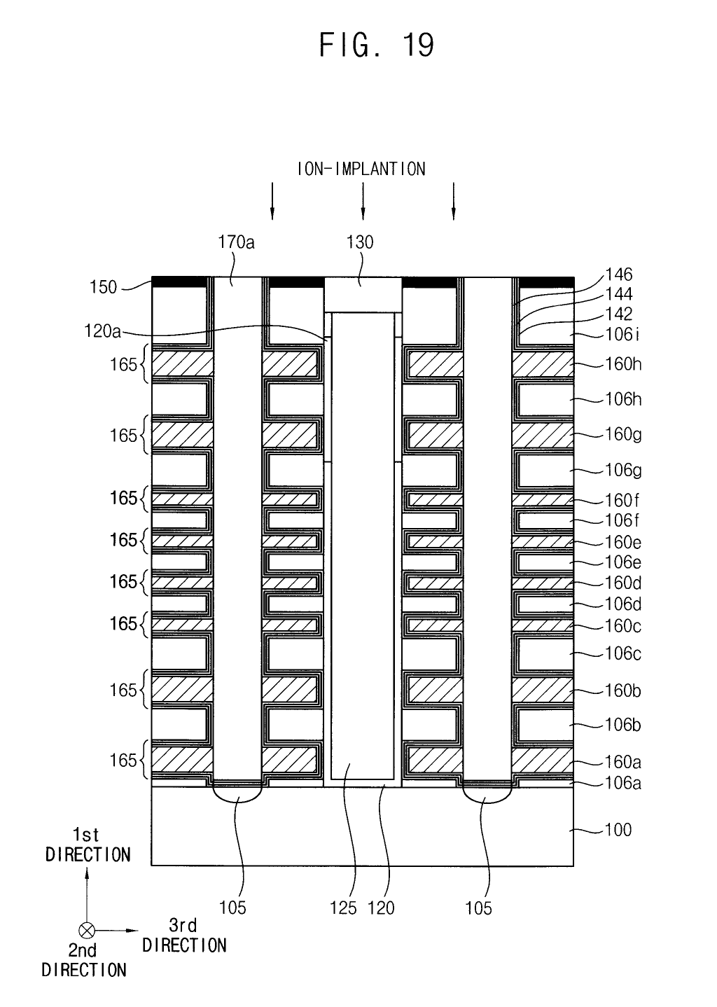

Referring to FIG. 19, a planarization process (e.g., an etch-back process) may be performed until a top surface of the etch-stop layer 150 is exposed to remove upper portions of the second insulation layer 170, the tunnel insulation layer 142, the charge trap layer 144 and the blocking layer 146, and the upper insulation layer pattern 109. A top surface of the preliminary pad 130 may be exposed. According to example embodiments, a top surface of the preliminary pad 130 may be coplanar with a top surface of the etch-stop layer 150. Processes substantially the same as or similar to those illustrated with reference to FIG. 12 may be performed to form a first impurity region 120a in the channel 120 and a pad 130a.

According to example embodiments, for example, an etch-back process may be performed until the top surface of the etch-stop layer 150 is exposed. Layer structures near the preliminary pad 130 may be uniformly removed so that impurities may be doped through the preliminary pad 130 into the channel 120 with uniformity. Doping profiles of the first impurity region 120a and the pad 130a may be uniform (e.g., improved uniformity).

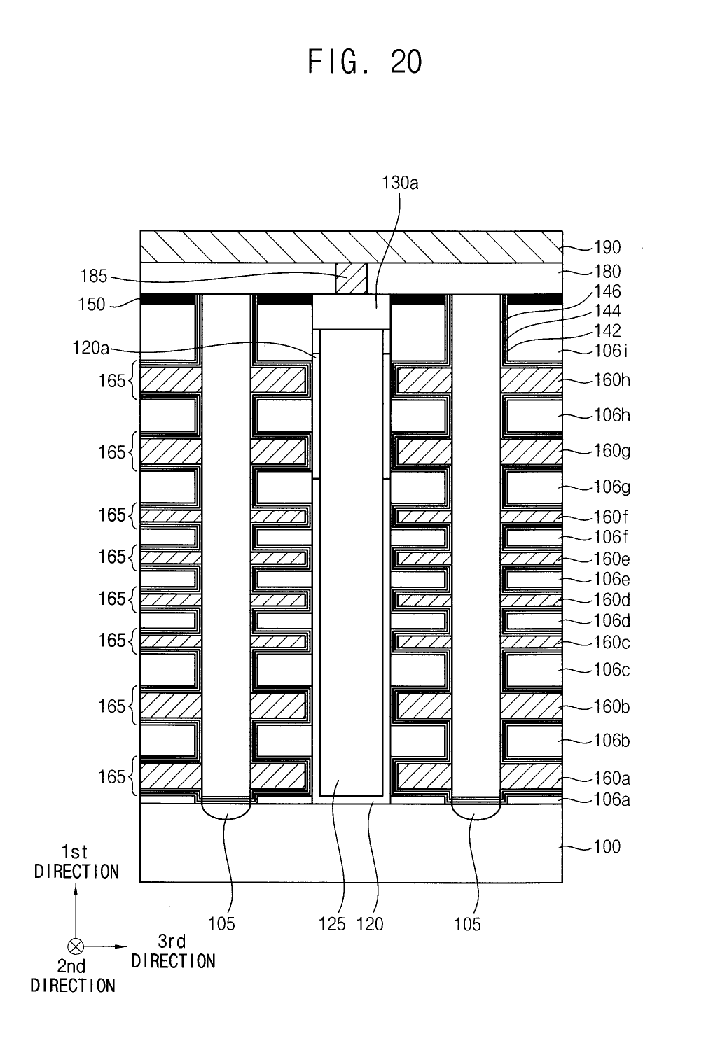

Referring to FIG. 20, processes substantially the same as or similar to those illustrated with reference to FIG. 13 may be performed to form an insulating interlayer 180, a bit line contact 185 and a bit line 190 so that a vertical memory device according to some example embodiments may be obtained.

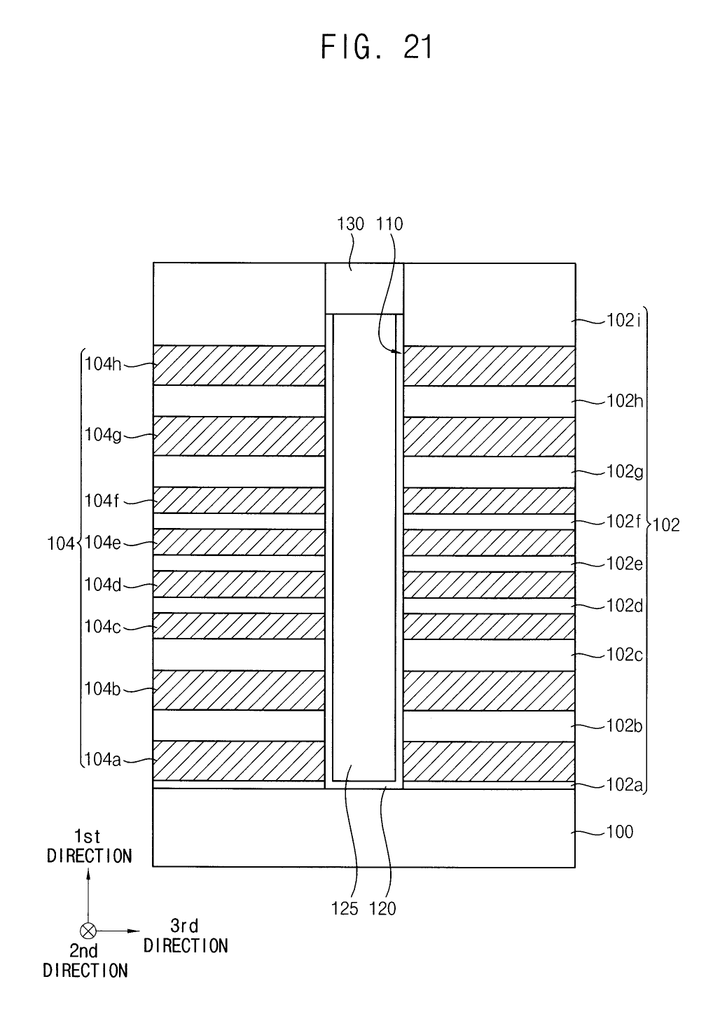

FIGS. 21-26 are cross-sectional diagrams illustrating methods of manufacturing vertical memory devices in accordance with still other example embodiments. The vertical memory devices may be substantially the same as or similar to vertical memory devices manufactured according to the methods illustrated with reference to FIG. 2-13 except for a position at which the etch-stop layer 150 is formed. Detailed explanations on substantially the same elements and/or methods may be omitted.

Referring to FIG. 21, processes the substantially the same as or similar to those illustrated with reference to FIGS. 2-5 may be performed. A first opening 110 that may expose a substrate 100 may be formed through sacrificial layers 104 and first insulation layers 102. A channel 120 and a filling layer pattern 125 may be formed in the first opening 110 and a preliminary pad 130 that may fill a remaining portion of the first opening 110 may be formed on the channel 120 and the filling layer pattern 125.

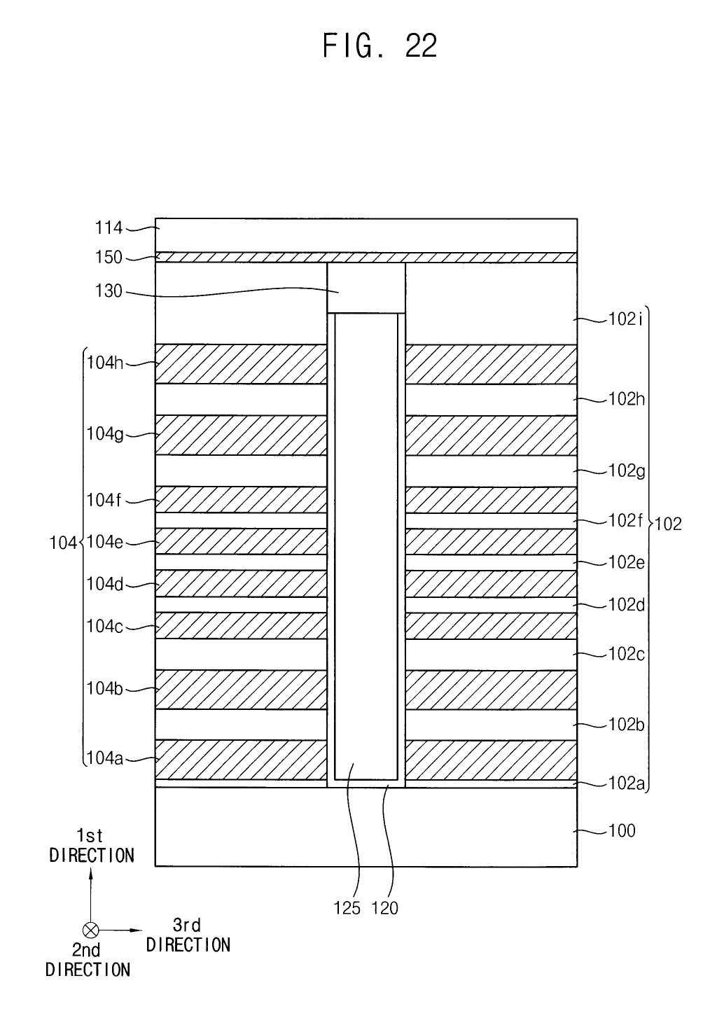

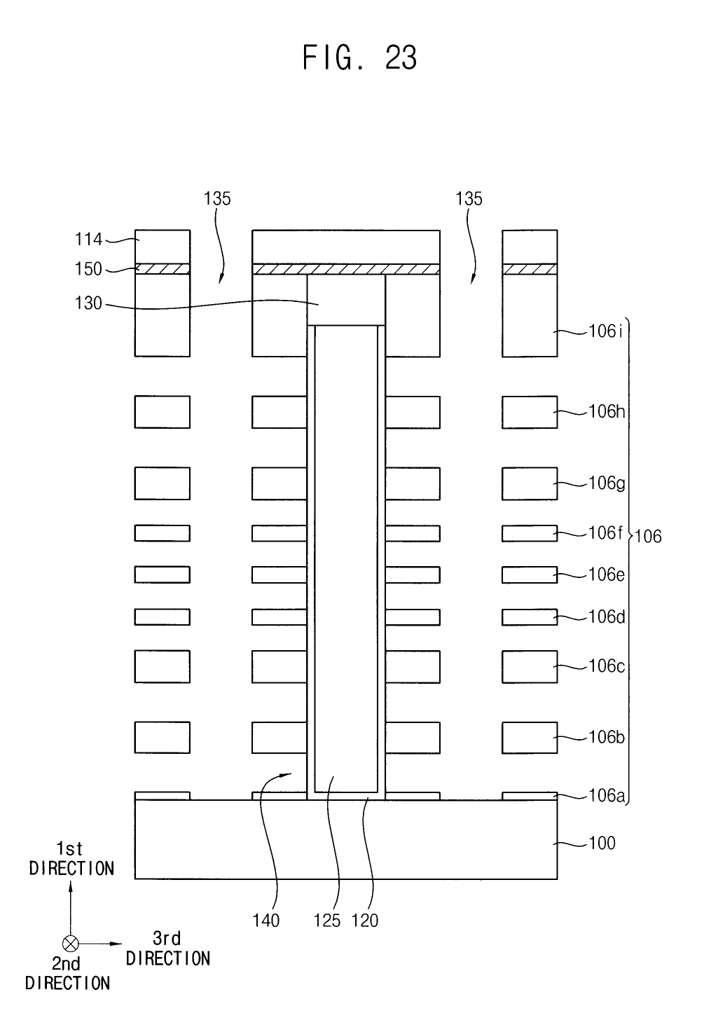

Referring to FIG. 22, an etch-stop layer 150 and an upper insulation layer 114 may be sequentially formed on an uppermost first insulation layer 102i and the preliminary pad 130. According to example embodiments, the etch-stop layer 150 may be formed using, for example, silicon oxide, silicon nitride, a metal oxide and/or the like. Referring to FIG. 23, processes substantially the same as or similar to those illustrated with reference to FIGS. 6 and 7 may be performed. Second openings 135 exposing the substrate 100 may be formed through the upper insulation layer 114, the etch-stop layer 150, the sacrificial layers 104 and the first insulation layers 102. The sacrificial layers 104 exposed inside the second opening 135 may be removed so that first insulation layer patterns 106 may remain on sidewalls of the channel 120 and the preliminary pad 130. Gaps 140 may be formed between the adjacent first insulation layer patterns 106.

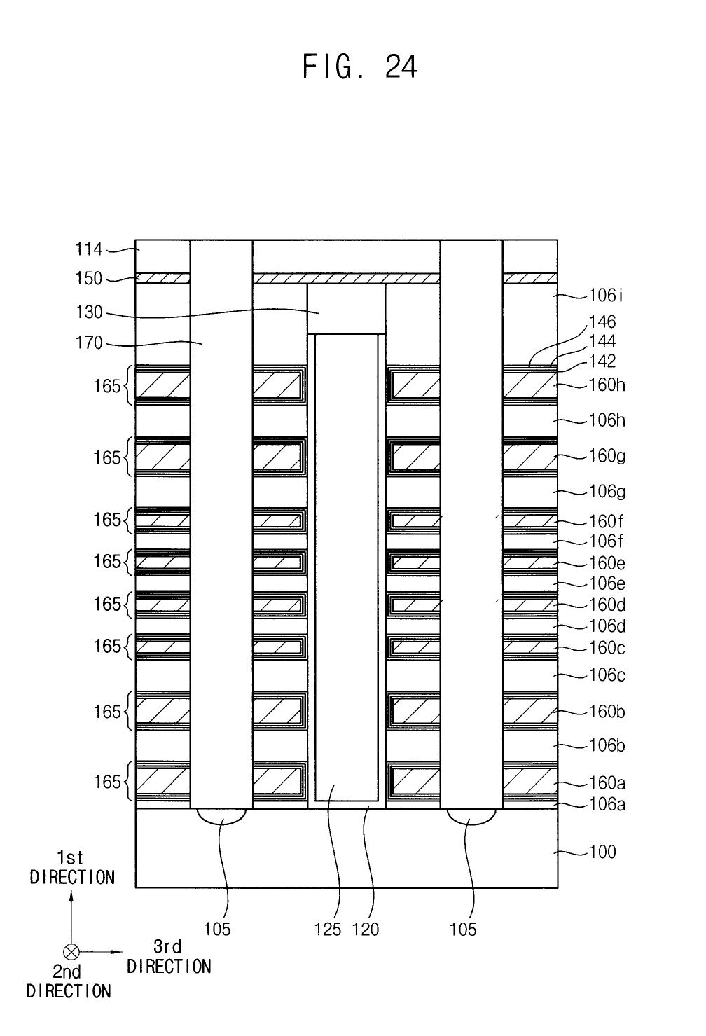

Referring to FIG. 24, processes substantially the same as or similar to those illustrated with reference to FIGS. 8-10 may be performed. A gate structure 165 including a tunnel insulation layer 142, a charge trap layer 144, a blocking layer 146 and a gate electrode 160 may be formed in the gap 140 at each level. Portions of the tunnel insulation layer 142, a charge trap layer 144, a blocking layer 146 that may be formed on sidewalls of the first insulation layer patterns 106, the etch-stop layer 150 and the upper insulation layer 114 and on the substrate 100 may be removed to form a third opening (not illustrated).

A second impurity region 105 may be formed at an upper portion of the substrate 100 exposed by the third opening. A second insulation layer filling the third opening may be formed on the substrate 100 and the upper insulation layer 114. An upper portion of the second insulation layer may be planarized until a top surface of the upper insulation layer 114 may be exposed to form a second insulation layer pattern 170.

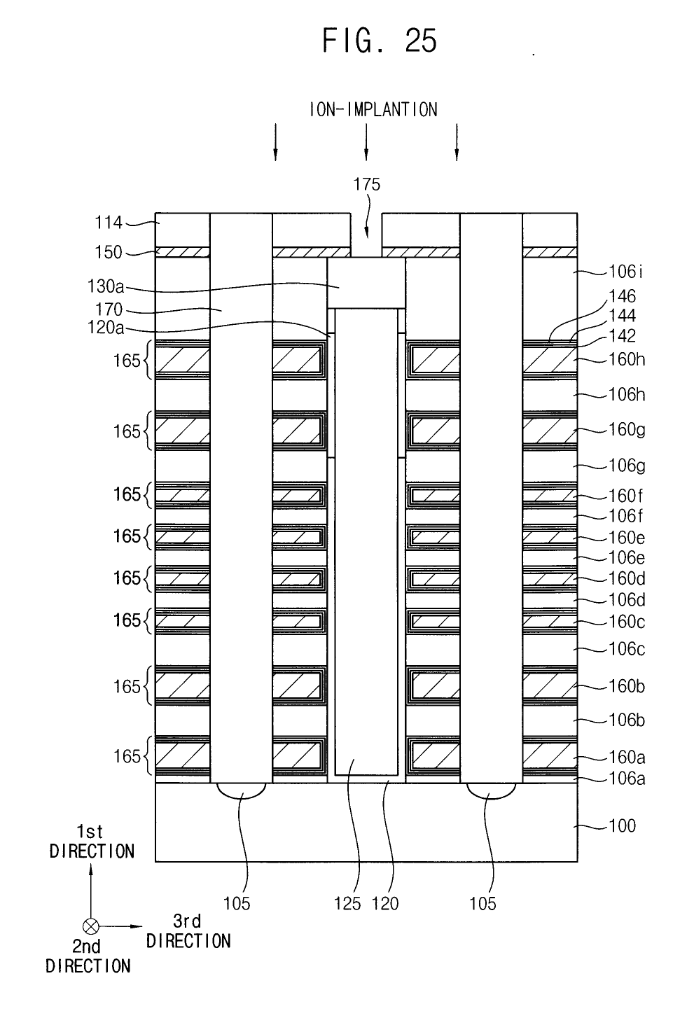

Referring to FIG. 25, a fourth opening 175 that may expose a top surface of the preliminary pad 130 may be formed through the upper insulation layer 114 and the etch-stop layer 150. Processes substantially the same as or similar to those illustrated with reference to FIG. 12 may be performed. Impurities may be implanted through the preliminary pad 130, that may be exposed, to form a first impurity region 120a and the pad 130a. According to example embodiments, the etch-stop layer 150 may be formed to a uniform height from the top surface of the preliminary pad 130 so that the impurities may be doped with uniformity at a desired depth and/or a desired position.

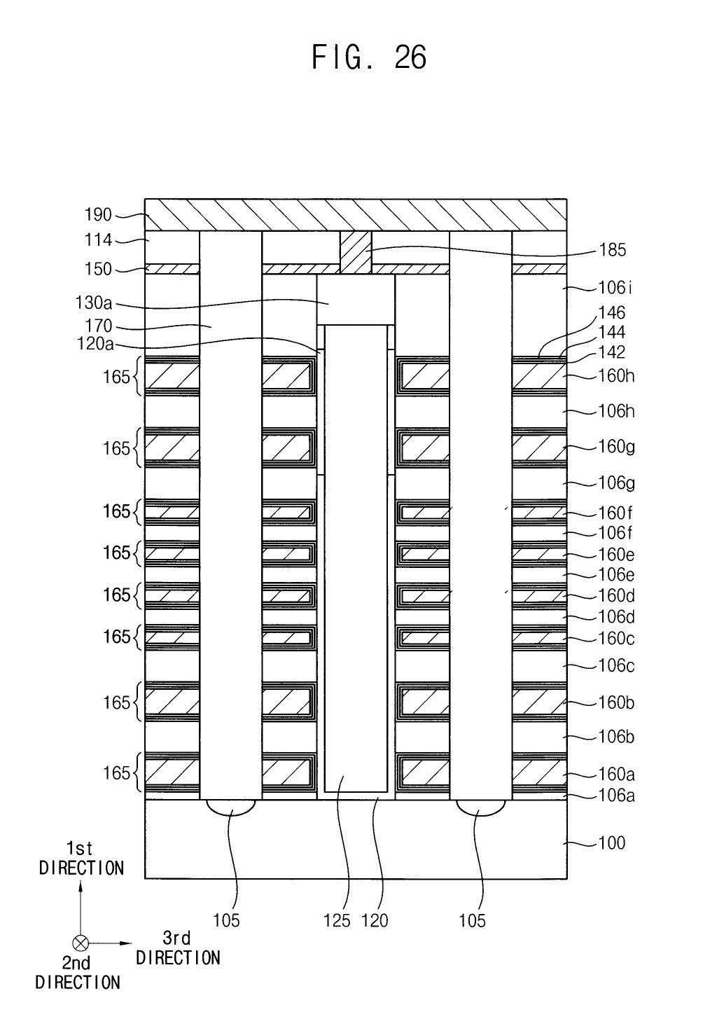

Referring to FIG. 26, a bit line contact 185 filling the fourth opening 175 may be formed on the pad 130a. A bit line 190 may be formed on the upper insulation layer 114 and the second insulation layer pattern 170 so they may be electrically connected to the bit line contact 185.

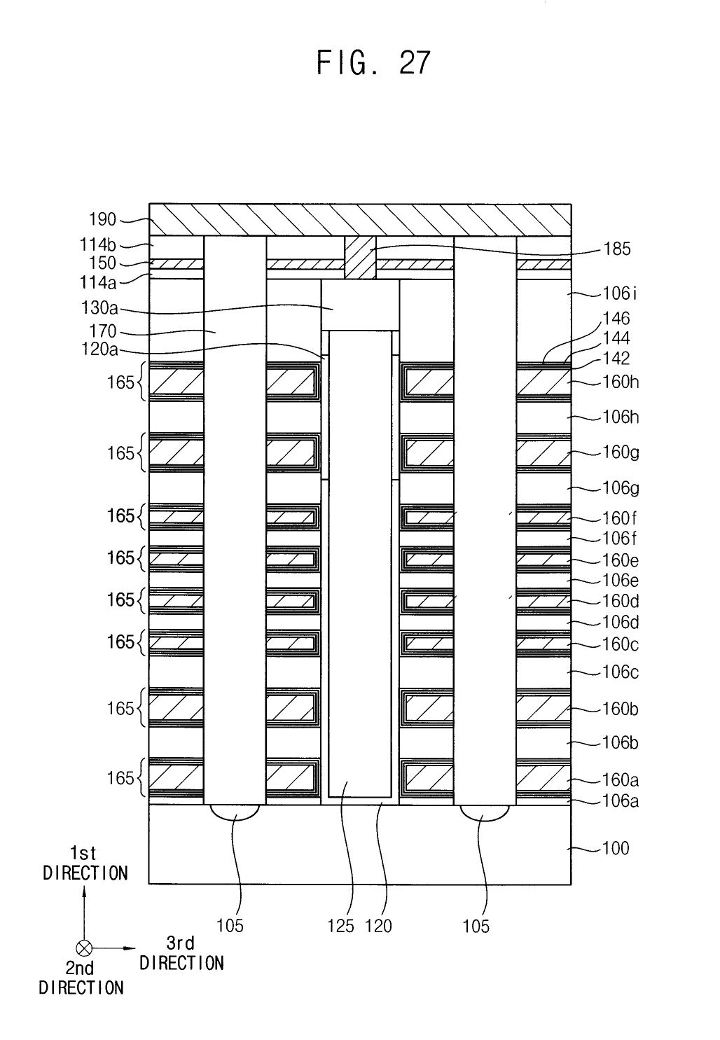

FIG. 27 is a cross-sectional diagram illustrating methods of manufacturing vertical memory devices in accordance with still other example embodiments. Referring to FIG. 27, an etch-stop layer 150 may be formed to be spaced apart from the pad 130a in a first direction. A first upper insulation layer 114a may be formed between the etch-stop layer 150 and an uppermost first insulation layer pattern 106i, and between the etch-stop layer 150 and the pad 130a. A second upper insulation layer 114b may be formed on the etch-stop layer 150. Other processes may be substantially the same as or similar to those illustrated with reference to FIGS. 21-26. Thus, detailed explanations thereof may be omitted.

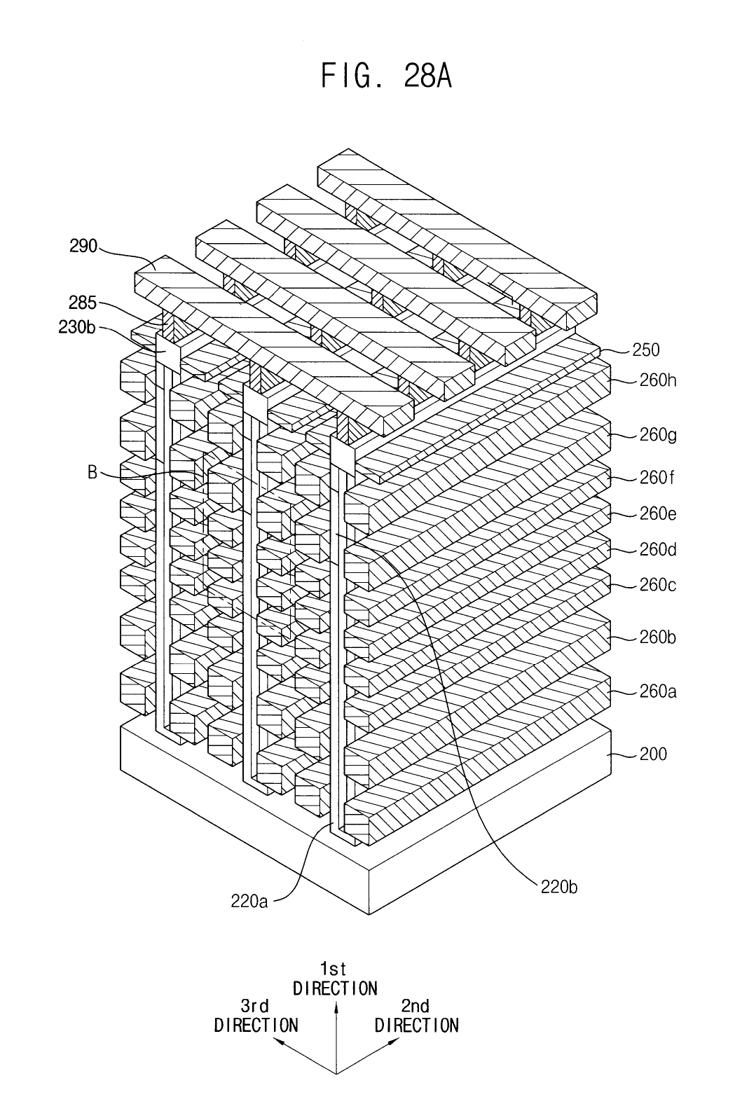

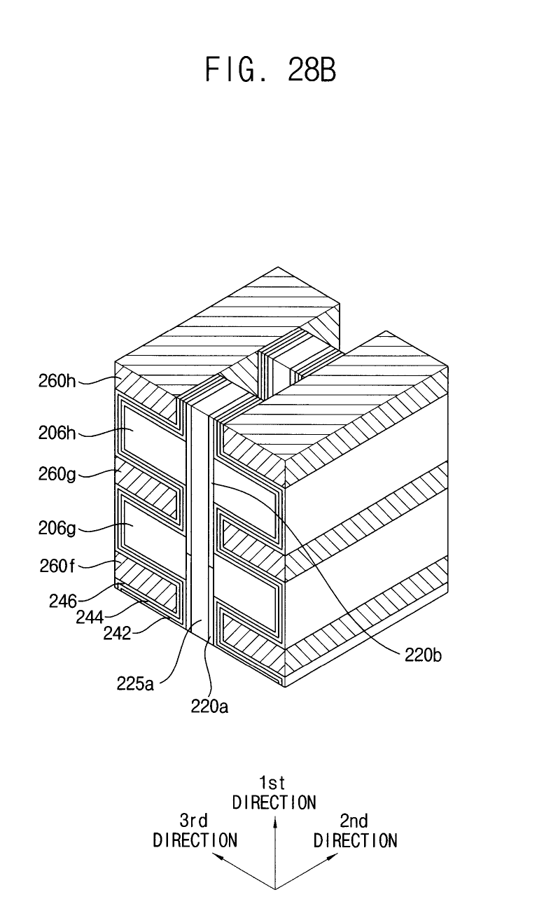

FIGS. 28A and 28B are a perspective diagram and a local perspective diagram, respectively, illustrating vertical memory devices in accordance with example embodiments. FIG. 28B is a magnified perspective view of region B of a vertical memory device illustrated in FIG. 28A. A structure of the vertical memory device may be substantially the same as or similar to the structure illustrated with reference to FIGS. 1A-1C except for shapes of a channel, a filling layer pattern, a pad and an insulation layer pattern. Detailed explanations of substantially the same elements and/or methods may be omitted.

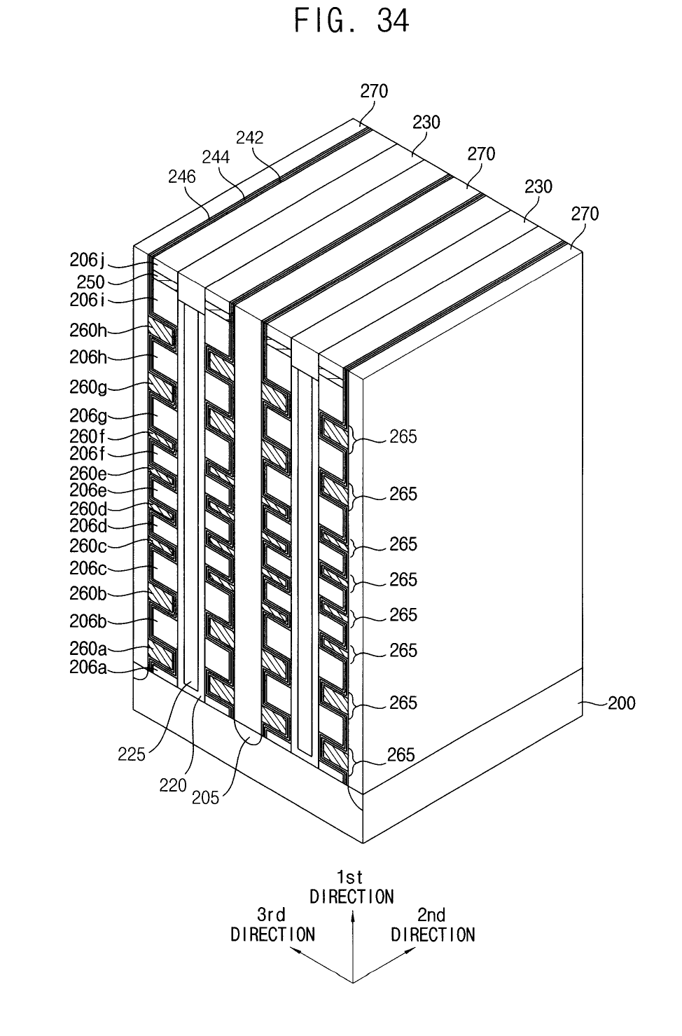

Referring to FIGS. 28A and 28b, the vertical memory device may include a channel pattern 220a that may extend in a first direction substantially perpendicular to a top surface of a substrate 200 and a plurality of gate structures 265 (see FIG. 34) on an outer sidewall of the channel pattern 220a. The gate structures 265 may be spaced apart from each other along the first direction and each gate structure 265 may extend in a second direction that may be substantially perpendicular to the first direction. The vertical memory device may include a bit line 290 that may be electrically connected to the channel pattern 220a and a second impurity region 205 (see FIG. 34).

A pad pattern 230b may be on the channel pattern 220a and an etch-stop layer 250 that may extend in the second direction may be on a sidewall of the pad pattern 230b. First insulation layer patterns 206 may be in spaces between the substrate 200, the gate structures 265 and the etch-stop layer 250. According to example embodiments, a plurality of the channel patterns 220a may be along the second direction and may form a channel row. A plurality of the channel rows may be along a third direction that may be substantially perpendicular to the second direction.

The channel pattern 220a may include a first impurity region 220b that may be doped with a first impurity. According to example embodiments, the first impurity region 220b may include p-type impurities (e.g., indium and/or gallium). According to example embodiments, the first impurity region 220b may be at a portion of the channel pattern 220a adjacent gate electrodes 260g and 260h that serve as a SSL(s). The first impurity region 220b may be formed to a uniform depth. A filling layer pattern 225a may be between both inner sidewalls of the channel pattern 220a. The filling layer pattern 225a may be substantially pillar shaped.

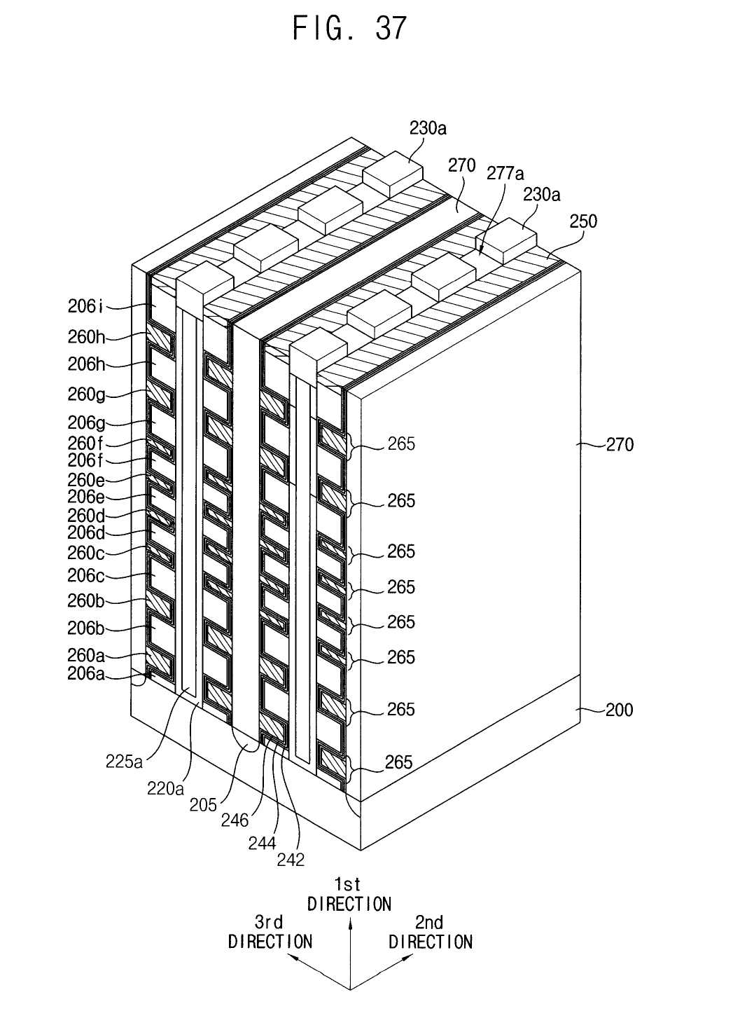

The pad pattern 230b may be on the filling layer pattern 225a and the channel pattern 220a to electrically connect the channel pattern 220a to a bit line contact 285. According to example embodiments, the pad pattern 230b may include n-type impurities, for example, phosphorous, arsenic and/or the like. A plurality of structures including the channel pattern 220a, the filling layer pattern 225a and the pad pattern 230b may be arranged along the second direction. The structures may be insulated from each other by a third insulation layer pattern 277a (see FIG. 37). The third insulation layer pattern 277a may be substantially pillar shaped and may extend in the first direction. A plurality of the third insulation layer patterns 277a may be arranged along the second direction to form a third insulation layer pattern row. A plurality of the third insulation layer pattern rows may be along the third direction.

Each gate structure 265 may include a gate electrode 260, a tunnel insulation layer 242, a charge trap layer 244 and a blocking layer 246. The tunnel insulation layer 242, the charge trap layer 244 and the blocking layer 246 may be sequentially stacked conformally on surfaces of the first insulation layer patterns 206 and on an outer sidewall of the channel pattern 220a. According to an example embodiment, the tunnel insulation layer 242 may be formed only on the outer sidewall of the channel pattern 220a. The tunnel insulation layer 242, the charge trap layer 244 and the blocking layer 246 may not be formed on sidewalls of the first insulation layer patterns 206.

Two lowermost gate electrodes 260a and 260b may serve as a GSL(s) and the uppermost gate electrodes 260g and 260h may serve as a SSL(s). Four gate electrodes 260c, 260d, 260e and 260f between the GSL and the SSL may serve as word lines. Each of the GSL(s) and the SSL(s) may be formed at 2 levels and the word lines may be formed at 4 levels. According to at least one example embodiment, each of the GSL and the SSL may be formed at 1 level and a word line may be formed at 2, 8 or 16 levels.

A second insulation layer pattern 270 (see FIG. 34) may be between structures including the gate structures 265 and the first insulation layer patterns 206 alternately stacked on each other. A second impurity region 205 (FIG. 34) may be at an upper portion of the substrate 200 beneath the second insulation layer pattern 270. The second impurity region 205 may extend in the second direction and serve as a CSL.

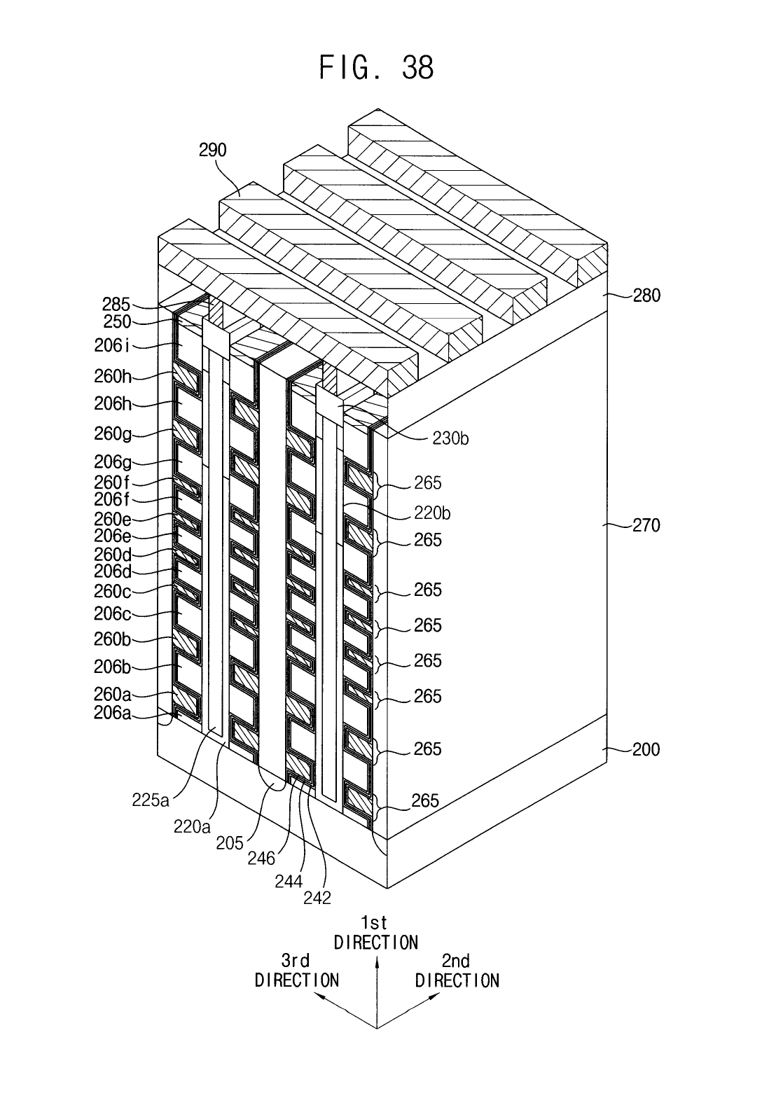

The bit line 290 may be electrically connected to the pad pattern 230b via the bit line contact 285. The bit line 290 may be electrically connected to the channel pattern 220a. According to example embodiments, the bit line 290 may extend in the third direction. The bit line contact 285 may make contact with the pad pattern 230b through an insulating interlayer 280 (see FIG. 38). The insulating interlayer 280 may be on the etch-stop layer 250, the second insulation layer pattern 270, the third insulation layer pattern 277a and the pad pattern 230b. According to some example embodiments, a top surface of the etch-stop layer 250 may be coplanar with a top surface of the pad pattern 230b. According to at least one example embodiment, the etch-stop layer 250 may be over the pad pattern 230b.

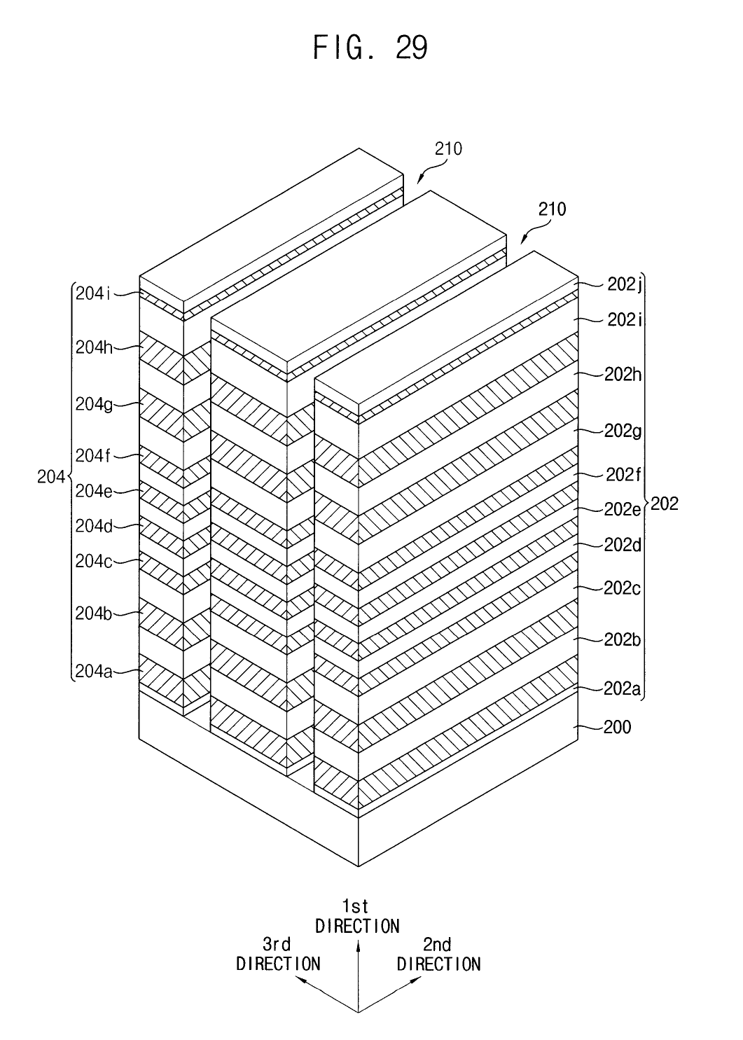

FIGS. 29-38 are perspective diagrams illustrating methods of manufacturing a vertical memory device of FIGS. 28A and 28B in accordance with example embodiments. Referring to FIG. 29, processes substantially the same as or similar to those illustrated with FIGS. 2 and 3 may be performed. First insulation layers 202 and sacrificial layers 204 may be alternately and repeatedly formed on a substrate 200. The first insulation layers 202 and the sacrificial layers 204 may be partially removed to form a first opening 210 that may expose the substrate 200. The first opening 210 may extend in a second direction that may be substantially parallel to a top surface of the substrate 200. A plurality of the first openings 210 may be formed along a third direction that may be substantially perpendicular to the second direction.

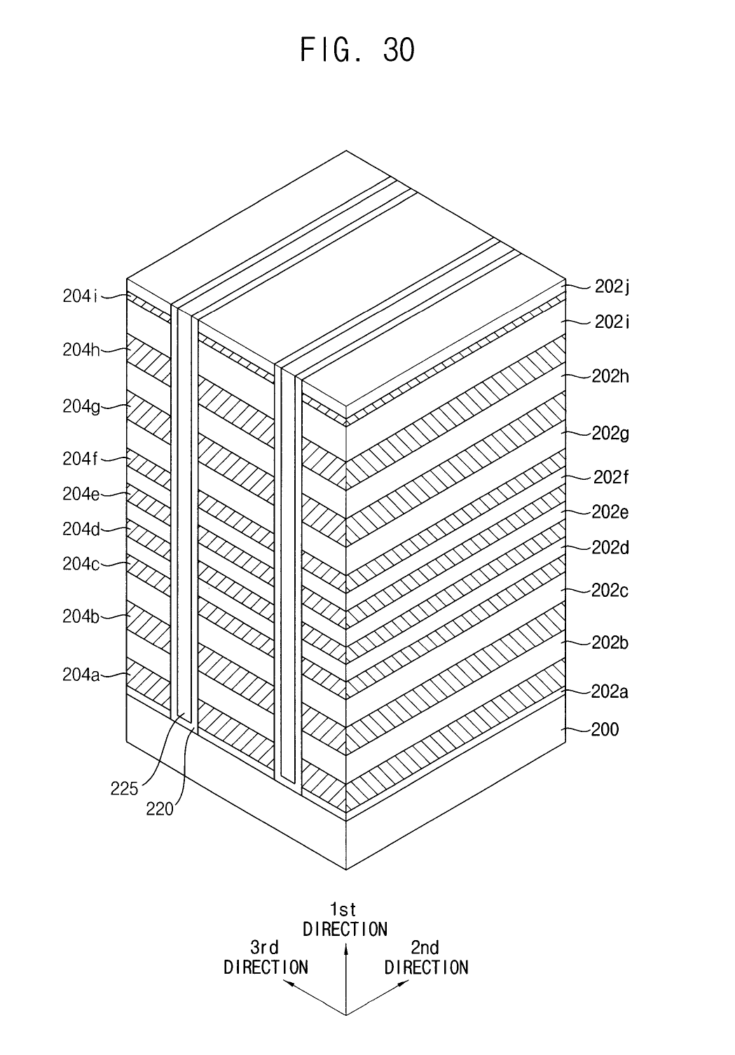

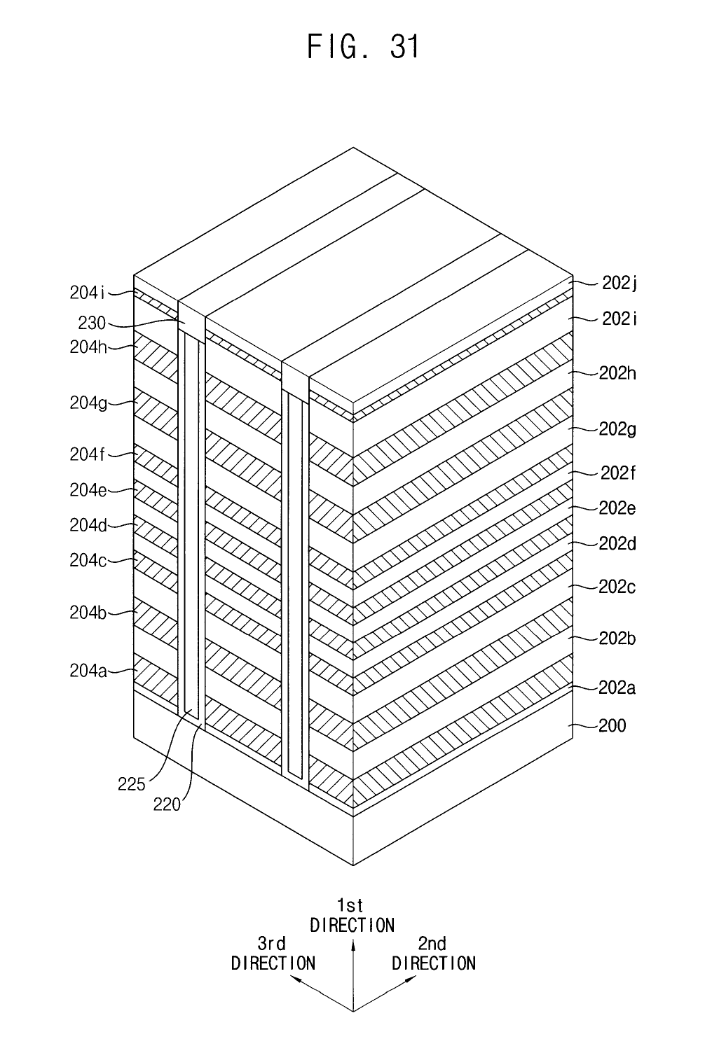

Referring to FIG. 30, processes substantially the same as or similar to those illustrated with reference to FIG. 4 may be performed. A channel 220 may be formed on surfaces inside the first opening 210 and a filling layer 225 filling a remaining portion of the first opening 210 may be formed on the channel 220. The channel 220 may be formed using, for example, polysilicon and/or amorphous silicon. Referring to FIG. 31, processes substantially the same as or similar to those illustrated with reference to FIG. 5 may be performed. A preliminary pad 230 may be formed on the filling layer 225 and the channel 220. The preliminary pad 230 may be formed using, for example, polysilicon and/or amorphous silicon.

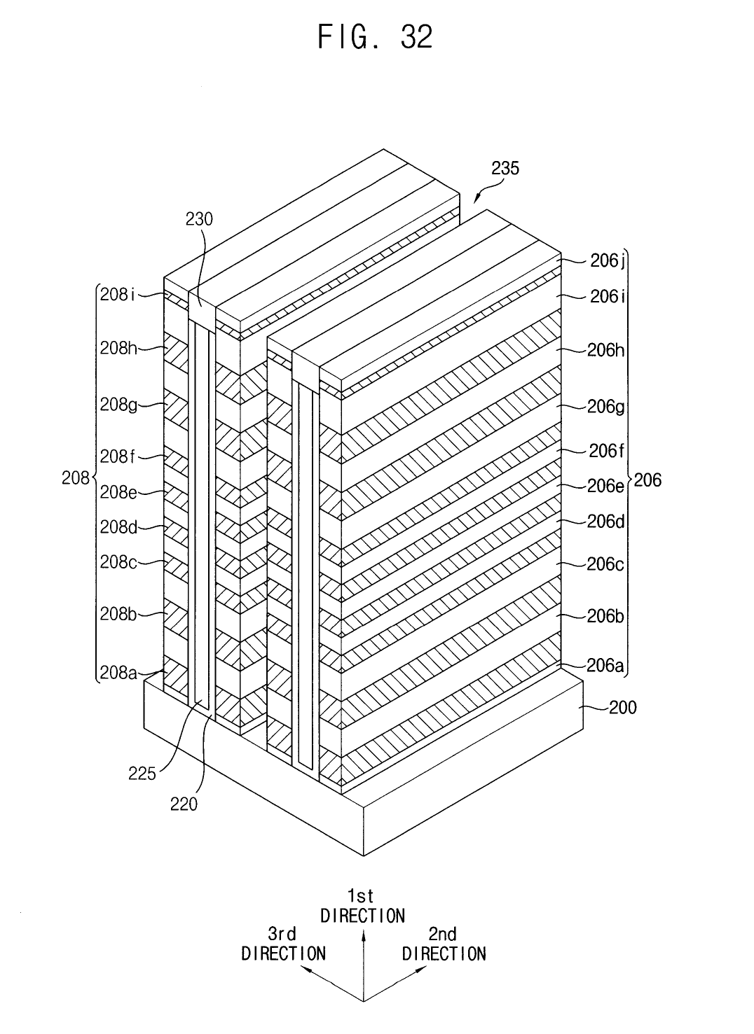

Referring to FIG. 32, processes substantially the same as or similar to those illustrated with reference to FIG. 6 may be performed. A second opening 235 exposing the substrate 200 through the first insulation layers 202 and the sacrificial layers 204 may be formed. According to example embodiments, the second opening 235 may extend in the second direction and a plurality of the second openings 235 may be formed along the third direction. By forming the second opening 235, the first insulation layers 202 and the sacrificial layers 204 may be transformed into first insulation layer patterns 206 and sacrificial layer patterns 208, respectively. The first insulation layer pattern 206 and the sacrificial layer pattern 208 at each level may extend in the second direction.

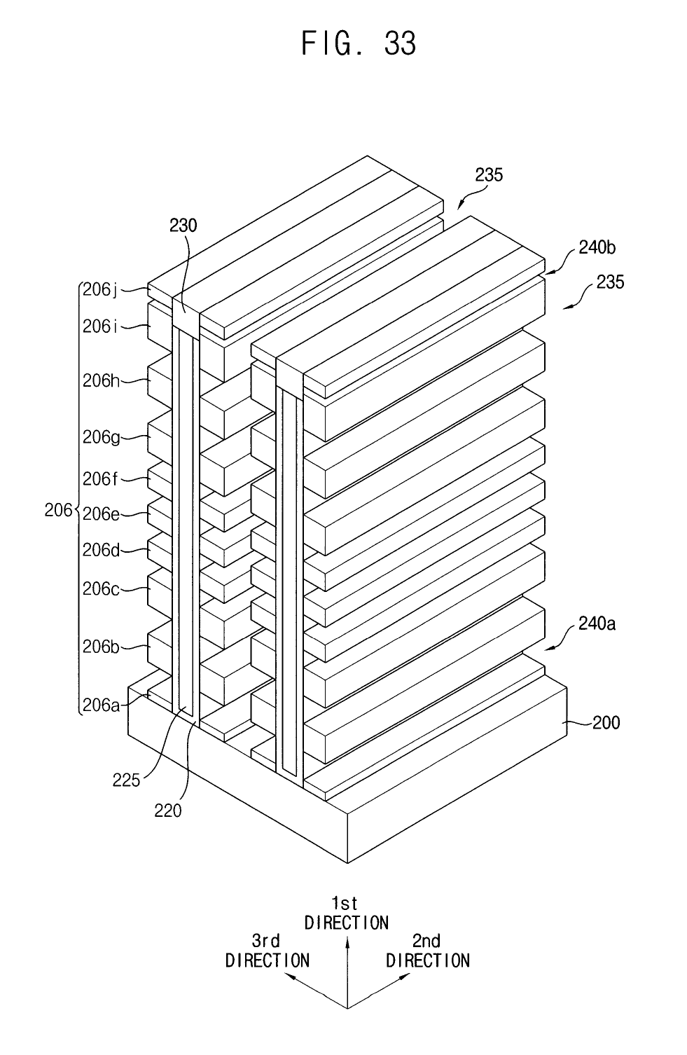

Referring to FIG. 33, processes substantially the same as or similar to those illustrated with reference to FIG. 7 may be performed. The sacrificial layer patterns 208 may be removed to form first gaps 240a and a second gap 240b. A width of the second gap 240b may be less than a width of the first gap 240a. The first and second gaps 240a and 240b may extend in the second direction.

Referring to FIG. 34, processes substantially the same as or similar to those illustrated with reference to FIGS. 8-10 may be performed. A tunnel insulation layer 242, a charge trap layer 244 and a blocking layer 246 may be formed on an outer sidewall of the channel 220 exposed by the first gaps 240a and on surfaces of the first insulation layer patterns 206. Gate electrodes 260 filling remaining portions of the first gaps 240a may be formed on the blocking layer 246. Gate structures 265 each of which may include the tunnel insulation layer 242, the charge trap layer 244, the blocking layer 246 and the gate electrode 260 may be formed in the first gaps 240a.

Two lowermost gate electrodes 260a and 260b may serve as a GSL(s) and two uppermost gate electrodes 260g and 260h may serve as a SSL(s). Four gate electrodes 260c, 260d, 260e and 260f between the GSL and the SSL may serve as word lines. The second gap 240b may be formed to a very narrow width. The second gap 240b may be completely filled with the tunnel insulation layer 242, the charge trap layer 244 and/or the blocking layer 246. An etch-stop layer 250 may be formed in the second gap 240b.

A third opening (not illustrated) may be formed between structures including the first insulation layer patterns 206, the gate structures 265 and the etch-stop layer 250. The third opening may extend in the second direction and expose the substrate 200. A second impurity region 205 may be formed at an upper portion of the substrate 200 exposed by the third opening. A second insulation layer (not illustrated) filling the third opening may be formed on the substrate 200, the first insulation layer pattern 206j and the preliminary pad 230. An upper portion of the second insulation layer may be planarized until a top surface of the first insulation layer pattern 206j is exposed to form a second insulation layer pattern 270 filling the third opening.

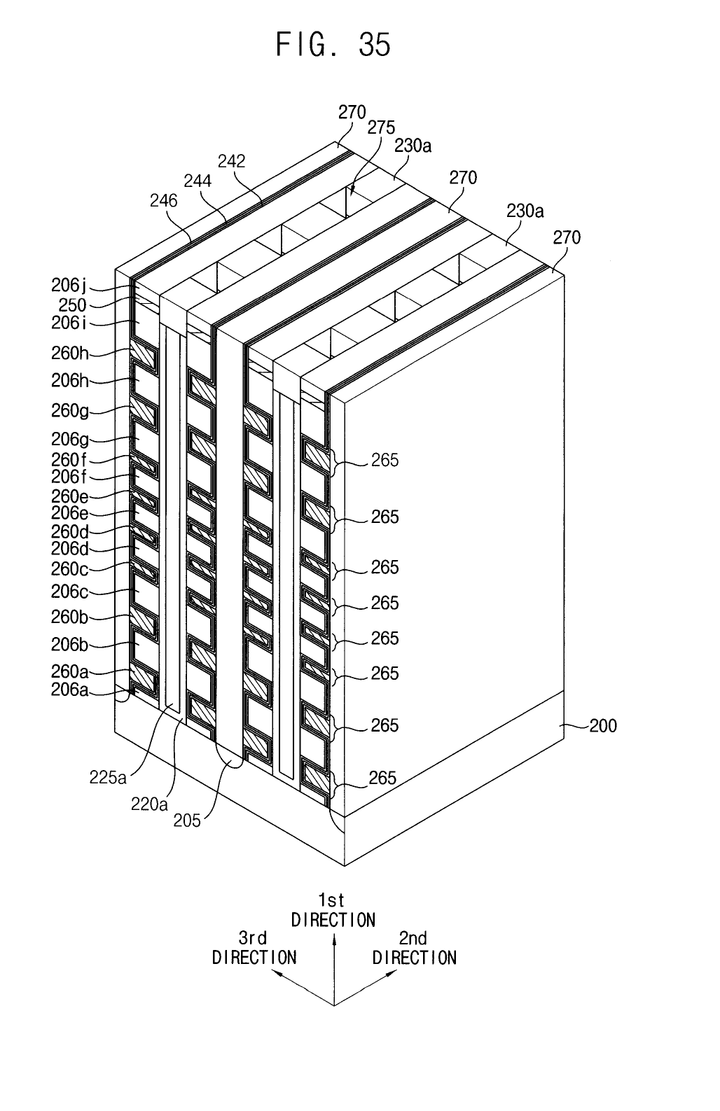

Referring to FIG. 35, the preliminary pad 230, the channel 220 and the filling layer 225 may be partially removed to form a fourth opening 275. According to example embodiments, the fourth opening 275 may extend in the first direction and a plurality of the fourth openings 275 may be formed along the second direction. By forming the fourth openings 275, the channel 220, the filling layer 225 and the preliminary pad 230 may be transformed into channel patterns 220a, filling layer patterns 225a and the preliminary pad patterns 230a.

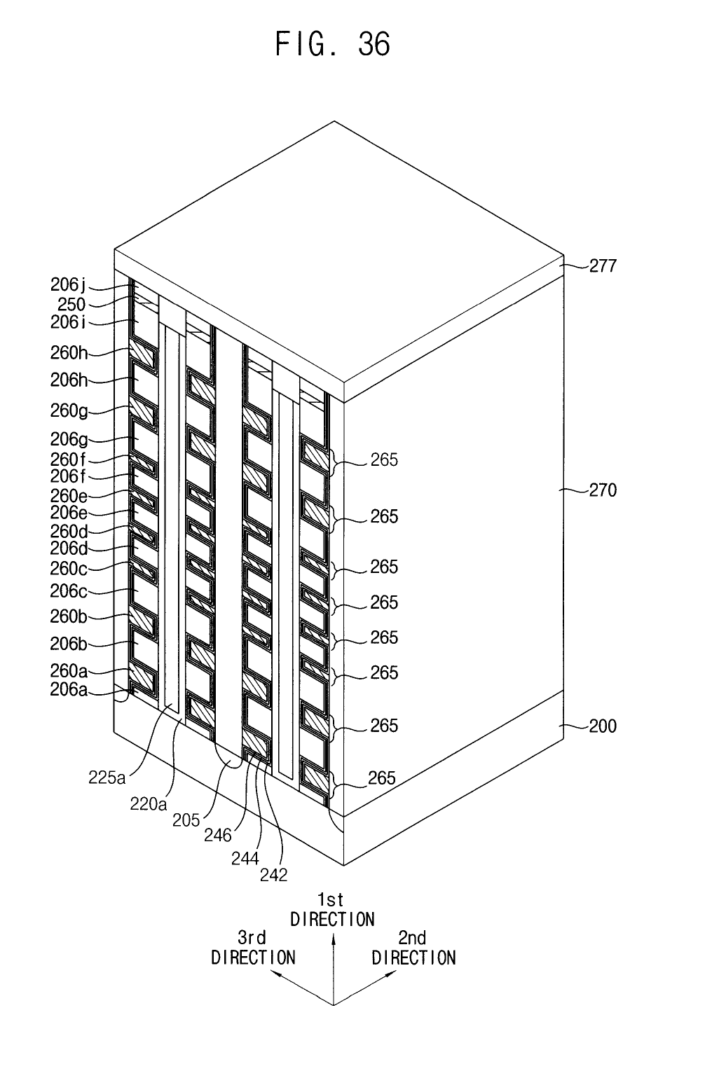

Referring to FIG. 36, a third insulation layer 277 filling the fourth openings 275 may be formed on the substrate 200, the first insulation layer pattern 206j, the second insulation layer pattern 270 and the preliminary pad pattern 230a. According to example embodiments, the third insulation layer may be formed using an insulating material, for example, a silicon oxide. Referring to FIG. 37, processes substantially the same as or similar to those illustrated with reference to FIG. 11 may be performed. An etch-back process may be performed until a top surface of the etch-stop layer 250 is exposed to remove upper portions of the third insulation layer 277, the second insulation layer pattern 270, the tunnel insulation layer 242, the charge trap layer 244 and the blocking layer 246, and the uppermost first insulation layer pattern 206j. An upper portion of the preliminary pad pattern 230a may be exposed.

While performing the etch-back process, the first insulation layer pattern 206j, the second insulation layer pattern 270 and the third insulation layer 277 near the preliminary pad pattern 230a may be uniformly removed due to the etch-stop layer 250. A height or a length of the exposed preliminary pad pattern 230a may be uniformly adjusted so that impurities may be implanted through the preliminary pad pattern 230a by a subsequent ion-implantation process to form a first impurity region 220b at a uniform depth and/or a position. By removing the upper portion of the third insulation layer 277, a third insulation layer pattern 277a may be formed between structures including the channel pattern 220a, the preliminary pad pattern 230a and the filling layer pattern 225a.

Referring to FIG. 38, processes substantially the same as or similar to those illustrated with reference to FIGS. 12 and 13 may be performed. An ion-implantation process may be performed through the exposed upper portion of the preliminary pad pattern 230a to form the first impurity region 220b and the pad pattern 230b. An insulating interlayer 280 covering the pad pattern 230b may be formed on the etch-stop layer 250, the second insulation layer pattern 270 and the third insulation layer pattern 277a. The insulating interlayer 280 may be formed using, for example, an insulating material (e.g., a silicon oxide).

A bit line contact 285 contacting the pad pattern 230b may be formed through the insulating interlayer 280. The bit line contact 285 may be formed using, for example, a metal, a metal nitride, doped polysilicon and/or the like. A bit line 290 electrically connected to the bit line contact 285 may be formed on the insulating interlayer 280. The bit line 290 may be formed using, for example, a metal, a metal nitride, doped polysilicon and/or the like. According to example embodiments, the bit line 290 may extend in the third direction and a plurality of the bit lines 290 may be formed along the second direction.

According to some example embodiments, processes substantially the same as or similar to those illustrated with reference to FIGS. 14-20 may be performed so that a top surface of the etch-stop layer 250 may be substantially coplanar with a top surface of the pad pattern 230b. According to some example embodiments, processes substantially the same as or similar to those illustrated with reference to FIGS. 22-27 may be performed so that the etch-stop layer 250 may be formed to be on or over the pad pattern 230b.

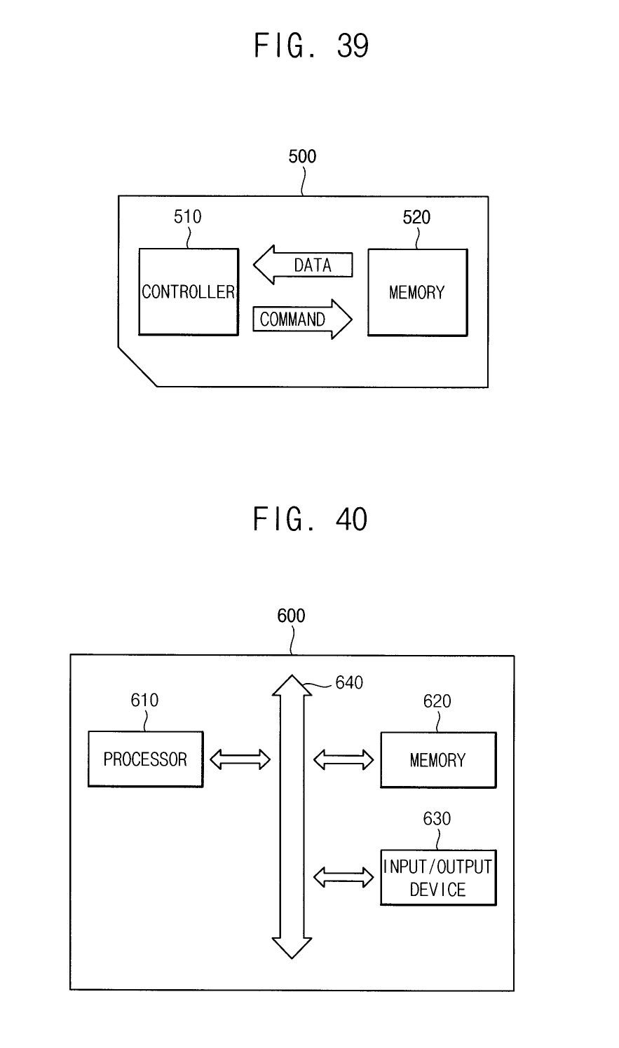

FIG. 39 is a schematic diagram illustrating memory cards 500 according to example embodiments. Referring to FIG. 39, a controller 510 and a memory 520 may exchange electrical signals. For example, according to commands of the controller 510, the memory 520 and the controller 510 may exchange commands and/or data. A memory card 500 may store data in the memory 520 and/or output data from the memory 520. The memory 520 may include one of the vertical memory devices described above with reference to FIGS. 1-38. A memory card 500 may be used as a storage medium for various portable electronic devices. For example, the memory card 500 may be a multimedia card (MMC) and/or a secure digital (SD) card.

FIG. 40 is a block diagram illustrating electronic systems 600 according to example embodiments. Referring to FIG. 40, a processor 610, an input/output device 630, and a memory 620 may perform data communication with each other by using a bus 640. The processor 610 may execute a program and/or control the electronic system 600. The input/output device 630 may be used to input/output data to/from the electronic system 600. The electronic system 600 may be connected to an external device (e.g. a personal computer and/or a network) by using the input/output device 630 and may exchange data with the external device.

The memory 620 may store code or programs for operations of the processor 610. For example, the memory 620 may include one of the vertical memory devices described above with reference to FIGS. 1-38. For example, an electronic system 600 may embody various electronic control systems requiring the memory 620, and, for example, may be used in mobile phones, MP3 players, navigation devices, solid state disks (SSD), and/or household appliances.

While example embodiments have been particularly shown and described, it will be understood by one of ordinary skill in the art that variations in form and detail may be made therein without departing from the spirit and scope of the claims.

1. A vertical memory device, comprising:
a channel extending in a first direction on a substrate, the channel including an impurity region, the first direction being perpendicular to a top surface of the substrate;
at least one ground selection line (GSL), a plurality of word lines and at least one string selection line (SSL) spaced apart from each other in the first direction on a sidewall of the channel;
a pad on a top surface of the channel; and
an etch-stop layer contacting the pad.

2. The vertical memory device of claim 1, wherein the impurity region is in a portion of the channel adjacent to the SSL.

3. Thee vertical memory device of claim 2, wherein a depth of the impurity region from the top surface of the channel is about uniform.

4. The vertical memory device of claim 1, wherein the channel is cup shaped.

5. The vertical memory device of claim 1, wherein the etch-stop layer is on a sidewall of the pad.

6. The vertical memory device of claim 5, wherein a top surface of the etch-stop layer is coplanar with a top surface of the pad.

7. The vertical memory device of claim 1, wherein the etch-stop layer is one of a double-layer structure including a silicon oxide and a silicon nitride, and a triple-layer structure including a silicon oxide, silicon nitride and a metal oxide.

8-16. (canceled)

17. A vertical memory device, comprising:
a channel on and extending perpendicularly to a support layer;
a pad on the channel, the channel between the pad and the support layer; and
an etch-stop layer adjacent to the pad.

18. The vertical memory device of claim 17, wherein the etch-stop layer is one of on a sidewall of the pad and on a top surface of the pad.

19. A memory card, comprising:
a controller; and
a memory including the vertical memory device of claim 1.

20. An electronic system, comprising:
a processor;
an input/output device;
a memory including the vertical memory device of claim 17; and
a bus connecting the processor, the input/output device and the memory.
